(19) United States
(12) Patent Application Publication
(10) Pub. No.: US 2024/0421061 A1
(43) Pub. Date: Dec. 19, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., SUWON-SI (KR)

(72) Inventor: JONGYOUN KIM, Suwon-si (KR)

(21) Appl. No.: 18/624,328

(22) Filed: Apr. 2, 2024

(30) Foreign Application Priority Data
Jun. 14, 2023 (KR) 10-2023-0076177

(51) Int. Cl. H01L 23/498; H01L 23/00; H01L 23/13; H01L 23/14; H01L 23/31; H01L 25/10

(52) U.S. Cl. CPC H01L 23/49833; H01L 23/13; H01L 23/14; H01L 23/3128; H01L 23/49838; H01L 25/105; H01L 24/16; H01L 24/32; H01L 24/48; H01L 24/73; H01L 2224/16225; H01L 2224/32145; H01L 2224/32225; H01L 2224/48147; H01L 2224/48227; H01L 2224/73204; H01L 2224/73265; H01L 2225/1052; H01L 2225/1058; H01L 2924/1815

(57) ABSTRACT

A semiconductor package includes a lower redistribution wiring layer having lower redistribution wirings, at least one semiconductor chip disposed on, and electrically connected to, the lower redistribution wiring layer, a sealing member disposed on the lower redistribution wiring layer and having a plurality of through vias that penetrate the sealing member and are electrically connected to the lower redistribution wirings, a dummy substrate layer stacked on the sealing member and the at least one semiconductor chip and having a plurality of through electrodes that penetrate the dummy substrate layer and are electrically connected to the plurality of through vias, and an upper redistribution wiring layer disposed on the dummy substrate layer and having upper redistribution wirings that are electrically connected to the plurality of through electrodes.

### CROSS-RELATED TO RELATED APPLICATION

This application claims priority under 35 U.S.C. § 119 to Korean Patent Application No. 10-2023-0076177, filed on Jun. 14, 2023, in the Korean Intellectual Property Office (KIPO), the contents of which are herein incorporated by reference in their entirety.

### TECHNICAL FIELD

Example embodiments relate to a semiconductor package and a method of manufacturing the semiconductor package. More particularly, example embodiments relate to a fan-out wafer level package and a method of manufacturing the same.

### DISCUSSION OF RELATED ART

In a fan-out wafer level package, a lower redistribution wiring layer may be relatively thin compared to a package substrate, and a relatively thick semiconductor chip may be mounted on the lower redistribution wiring layer. Due to an asymmetric structure between the top and the bottom of the package, warpage may occur in corner areas of the package. Further, as a thickness of the semiconductor chip increases, heat dissipation characteristics may be improved. However, the thickness of the semiconductor chip may be limited by a height of a copper post (Cu post) in a mold via, which may limit heat dissipation characteristics of the package.

### SUMMARY

Example embodiments provide a semiconductor package capable improving or preventing warpage and having improved dissipation characteristics.

Example embodiments provide a method of manufacturing the semiconductor package.

According to example embodiments, a semiconductor package includes a lower redistribution wiring layer having lower redistribution wirings, at least one semiconductor chip disposed on, and electrically connected to, the lower redistribution wiring layer, a sealing member disposed on the lower redistribution wiring layer and having a plurality of through vias that penetrate the sealing member and are electrically connected to the lower redistribution wirings, a dummy substrate layer stacked on the sealing member and the at least one semiconductor chip, the dummy substrate layer having a plurality of through electrodes that penetrate the dummy substrate layer and are electrically connected to the plurality of through vias, and an upper redistribution wiring layer disposed on the dummy substrate layer and having upper redistribution wirings that are electrically connected to the plurality of through electrodes.

According to example embodiments, a semiconductor package includes a lower structure including a lower redistribution wiring layer having lower redistribution wirings, at least one semiconductor chip disposed on the lower redistribution wiring layer, and a sealing member disposed on the lower redistribution wiring layer and having a plurality of through vias that penetrate the sealing member and are electrically connected to the lower redistribution wirings; an upper redistribution wiring layer disposed on the lower structure, the upper redistribution wiring layer having upper redistribution wirings; and a substrate structure interposed between the lower structure and the upper redistribution wiring layer, the substrate structure including a dummy substrate layer. A plurality of through electrodes are provided in the dummy substrate layer to penetrate the dummy substrate layer and electrically connect the plurality of through vias and the upper redistribution wirings.

According to example embodiments, a semiconductor package includes a lower redistribution wiring layer having lower redistribution wirings, at least one semiconductor chip disposed on the lower redistribution wiring layer, the at least one semiconductor chip having chip pads that are electrically connected to the lower redistribution wirings, a sealing member surrounding the at least one semiconductor chip and disposed on the lower redistribution wiring layer, the sealing member having a plurality of through vias that penetrate the sealing member and are electrically connected to the lower redistribution wirings, a first dielectric layer provided on an upper surface of the sealing member and having a plurality of first bonding pads that are connected to end portions of the plurality of through vias respectively, a second dielectric layer bonded to the first dielectric layer and having a plurality of second bonding pads that are in contact with the plurality of first bonding pads respectively, a dummy substrate layer stacked on the sealing member, the dummy substrate layer having a plurality of through electrodes that penetrate the dummy substrate layer and are electrically connected to the plurality of second bonding pads respectively, and an upper redistribution wiring layer disposed on the dummy substrate layer, the upper redistribution wiring layer having upper redistribution wirings that are electrically connected to the plurality of through electrodes.

According to example embodiments, a semiconductor package may include a lower redistribution wiring layer, at least one semiconductor chip disposed on the lower redistribution wiring layer, a sealing member surrounding at least a portion of the at least one semiconductor chip and disposed on an upper surface of the lower redistribution wiring layer and having a plurality of through vias that are provided to penetrate the sealing member, a dummy substrate layer stacked on an upper surface of the sealing member and having a plurality of through electrodes and a plurality of dummy through electrodes that are provided to penetrate the dummy substrate layer, and an upper redistribution wiring layer disposed on the dummy substrate layer.

The dummy substrate layer may cover a fan-in region and a fan-out region surrounding the fan-in region. The plurality of through electrodes may be provided to penetrate the dummy substrate layer in the fan-in region, and the plurality of dummy through electrodes may be provided to penetrate the dummy substrate layer in the fan-out region.

The dummy substrate layer may cover the fan-out region where relatively high warpage may occur, which may improve a warping of an edge region of the semiconductor package. The dummy substrate layer may serve as a heat spreader that spreads heat from the semiconductor chip and the dummy through electrodes may serve as heat dissipation passages to effectively dissipate heat from the semiconductor chip to the outside, which may improve heat dissipation characteristics.

### BRIEF DESCRIPTION OF THE DRAWINGS

Example embodiments will be more clearly understood from the following detailed description taken in conjunction with the accompanying drawings. FIGS. 1 to 27 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating a dummy substrate layer in FIG. 1.

FIG. 4, FIG. 5, FIG. 6, FIG. 7, FIG. 8, FIG. 9, FIG. 10, FIG. 11, FIG. 12, FIG. 13, FIG. 14, and FIG. 15 are views illustrating a method of manufacturing a semiconductor package in accordance with example embodiments.

FIG. 16 is a cross-sectional view illustrating a semiconductor package in accordance with example embodiments.

FIG. 17 is a cross-sectional view illustrating a semiconductor package in accordance with example embodiments.

FIG. 18 is a cross-sectional view illustrating a semiconductor package in accordance with example embodiments.

FIG. 19, FIG. 20, FIG. 21, FIG. 22, FIG. 23, FIG. 24, FIG. 25, FIG. 26, and FIG. 27 are cross-sectional views illustrating a method of manufacturing a semiconductor package in accordance with example embodiments.

### DETAILED DESCRIPTION

Hereinafter, example embodiments will be explained in detail with reference to the accompanying drawings.

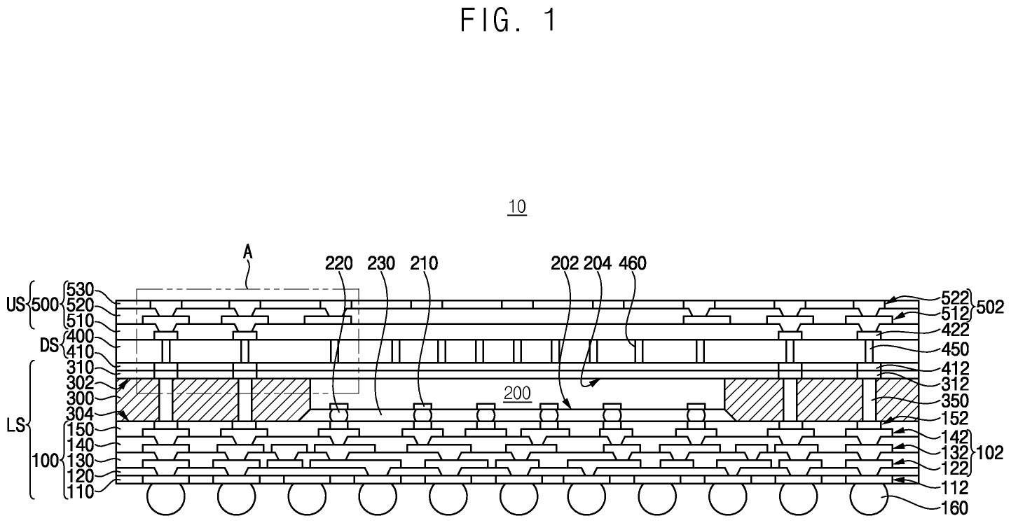

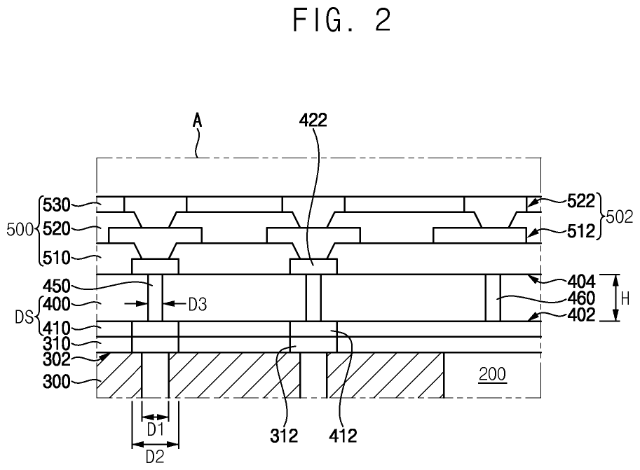

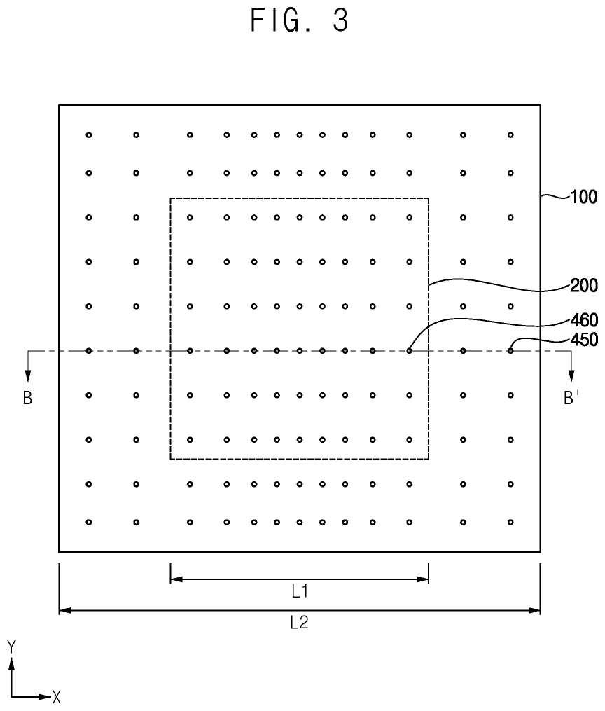

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating a dummy substrate layer in FIG. 1. FIG. 1 is a cross-sectional view taken along the line B-B′ in FIG. 3.

Referring to FIG . . . 1, FIG. 2, and FIG. 3, a semiconductor package 10 may include a lower structure LS, an upper structure US, and a substrate structure DS interposed between the lower structure LS and the upper structure US. The lower substructure LS may include a lower redistribution wiring layer 100, a semiconductor chip 200 disposed on the lower redistribution wiring layer 100, and a sealing member 300 covering at least a portion of the semiconductor chip 200 on an upper surface of the lower redistribution wiring layer 100. The substrate structure DS may include a dummy substrate layer 400 stacked on an upper surface 302 of the sealing member 300. The upper structure US may include an upper wiring redistribution wiring layer 500 disposed on the dummy substrate layer 400. In addition, the semiconductor package 10 may further include external connection members 160 disposed on an outer surface of the lower redistribution wiring layer 100.

In example embodiments, the semiconductor package 10 may have a square shape in a plan view, however the present disclosure is not limited thereto. For example, the semiconductor package 10 may have a circular shape, a rectangular shape, etc.

In example embodiments, the semiconductor package 10 may be a fan-out package in which the lower redistribution wiring layer 100 extends to the sealing member 300 covering a side surface of the semiconductor chip 200. The lower redistribution wiring layer 100 may be formed by a wafer level redistribution wiring process. Additionally, the semiconductor package 10 may be provided as a unit package on which a second package may be stacked.

Further, the semiconductor package 10 may be provided as a System In Package (SIP). For example, one or more semiconductor chips may be disposed on the lower redistribution wiring layer 100. The semiconductor chips may include a logic chip including a logic circuit and/or a memory chip. The logic chip may be a controller that controls memory chips. The memory chip may include various types of memory circuits, such as DRAM, SRAM, flash, PRAM, ReRAM, FeRAM, or MRAM.

In example embodiments, the lower redistribution wiring layer 100 may have first redistribution wirings 102 as lower redistribution wirings. The semiconductor chip 200 may be disposed on the lower redistribution wiring layer 100 to be electrically connected to the first redistribution wirings 102. The lower redistribution wiring layer 100 may be provided on a front surface 202 of the semiconductor chip 200 to serve as a front redistribution wiring layer. Accordingly, the lower redistribution wiring layer 100 may be a front redistribution wiring layer (FRDL) of the fan-out package.

In particular, the lower redistribution wiring layer 100 may include a plurality of first, second, third, fourth and fifth lower insulating layers 110, 120, 130, 140 and 150 and the first redistribution wirings 102 provided in the first, second, third, fourth and fifth lower insulating layers. The first redistribution wirings 102 may include first, second and third lower redistribution wirings 122, 132 and 142.

The first, second, third, fourth and fifth lower insulating layers may include a polymer or a dielectric layer. For example, the first, second, third, fourth and fifth lower insulating layers may include a photosensitive insulating layer such as photo imagable dielectric (PID). The first, second, third, fourth and fifth lower insulating layers may be formed by a vapor deposition process, a spin coating process, etc. The first redistribution wirings may include aluminum (Al), copper (Cu), tin (Sn), nickel (Ni), gold (Au), platinum (Pt), or an alloy thereof. The first redistribution wirings may be formed by a plating process, an electroless plating process, a vapor deposition process, etc.

In particular, a first connection pad 112 may be provided in the first lower insulating layer 110. The first connection pad 112 may be a bump pad. The bump pad may include a solder pad or a pillar pad. For example, the first connection pad may include copper (Cu), aluminum (Al), tin (Sn), nickel (Ni), gold (Au), platinum (Pt), or an alloy thereof.

The second lower insulating layer 120 may be formed on the first lower insulating layer 110. The first lower redistribution wiring 122 may be formed on the second lower insulating layer 120. The first lower redistribution wiring 122 may be electrically connected to the first connection pad 112 through a first opening that may be formed in the second lower insulating layer 120.

The third lower insulating layer 130 may be formed on the second lower insulating layer 120. The second lower redistribution wiring 132 may be formed on the second lower insulating layer 120. The second lower redistribution wiring 132 may be electrically connected to the first lower redistribution wiring 122 through a second opening that may be formed in the third lower insulating layer 130.

The fourth lower insulating layer 140 may be formed on the third lower insulating layer 130. The third lower redistribution wiring 142 may be formed on the third lower insulating layer 130. The third lower redistribution wiring 142 may be electrically connected to the second lower redistribution wiring 132 through a third opening that may be formed in the third lower insulating layer 130.

A second connection pad 152 may be disposed on the third lower redistribution wiring 142. A solder resist layer 150 serving as the fifth lower insulating layer may be formed on the fourth lower insulating layer 140 and may expose at least a portion of the second connection pad 152. The solder resist layer 150 may serve as a passivation layer.

The numbers and arrangements of the lower insulating layers and the lower redistribution wirings of the lower redistribution wiring layer are provided as examples, and it will be appreciated that the present invention is not limited thereto.

In example embodiments, the semiconductor chip 200 may have a plurality of chip pads 210 on a front surface 202, that is, an active surface thereof. The semiconductor chip 200 may be mounted on the lower redistribution wiring layer 100 such that the first surface on which the chip pads 210 are formed faces the lower redistribution wiring layer 100.

The semiconductor chip 200 may be mounted on the lower redistribution wiring layer 100. The semiconductor chip 200 may be mounted on the lower redistribution wiring layer 100 by a flip chip bonding method. The semiconductor chip 200 may be mounted on the lower redistribution wiring layer 100 via conductive bumps 220. The conductive bumps 220 may be disposed between the second connection pad 152 on the third lower redistribution wiring 142 of the lower redistribution wiring layer 100 and the chip pad 210 of the semiconductor chip 200 and electrically connect them. For example, the conductive bump 220 may include a pillar bump formed on the chip pad 210 of the semiconductor chip 200 and a solder bump formed on the pillar bump. Alternatively, the conductive bump 220 may include only a solder bump formed on the chip pad 210 of the semiconductor chip 200. An underfill member 230 may be disposed between the semiconductor chip 200 and the lower redistribution wiring layer 100.

Although only a few chip pads are illustrated in the figures, the structures and arrangements of the chip pads are provided as examples, and it will be understood that the present invention is not limited thereto. Additionally, although only one semiconductor chip is illustrated, it may not be limited thereto, and a plurality of semiconductor chips may be stacked on the lower redistribution wiring layer.

In example embodiments, the sealing member 300 may cover at least a portion of the semiconductor chip 200 on the upper surface of the lower redistribution wiring layer 100. The sealing member 300 may cover the upper surface of the lower redistribution wiring layer 100 around the semiconductor chip 200. The sealing member 300 may expose an upper surface 204 of the semiconductor chip 200. Alternatively, the sealing member 300 may be formed to cover the upper surface 204 of the semiconductor chip 200. In this case, the sealing member 300 may include a first molding portion covering the upper surface 204 of the semiconductor chip 200 and a second molding portion covering the upper surface of the lower redistribution wiring layer 100 around the semiconductor chip 200.

For example, the sealing member 300 may include an epoxy mold compound (EMC). The sealing member 300 may be formed by a molding process, a screen printing process, a lamination process, etc.

In example embodiments, a plurality of through vias 350 may extend in a vertical direction to penetrate the sealing member 300. The through via 350 may be formed on the second connection pad 152 on the third lower redistribution wiring 142.

The through via 350 may be provided to penetrate the sealing member 300 and may serve as an electrical connector. The through via 350 may be a through mold via (TMV) formed to penetrate the sealing member 300. That is, the through vias 350 may be provided in the fan-out region outside the area where the semiconductor chip 200 may be disposed to electrically connect the lower redistribution wiring layer 100 and the upper redistribution wiring layer 500. For example, the through vias 350 may be provided in the fan-out region surrounding the semiconductor chip 200. A diameter D1 of each of the through vias 350 may be within a range of about 30 micrometers (μm) to 300 μm.

In example embodiments, the lower structure LS may further include a first dielectric layer 310 provided on an upper surface 302 of the sealing member 300. A plurality of first bonding pads 312 may be provided in the first dielectric layer 310 to be connected to end portions of the plurality of through vias 350 respectively.

The first dielectric layer 310 may be provided on an upper surface of the semiconductor chip 200. The first dielectric layer 310 may be a continuous, uninterrupted layer in an area above the semiconductor chip 200. For example, no through vias may be formed in the first dielectric layer 310 on the semiconductor chip 200.

The first bonding pads 312 may be electrically connected to the through vias 350. An upper surface of the first bonding pad 312 may be located on the same plane as an upper surface of the first dielectric layer 310. For example, the first dielectric layer 310 may include silicon oxide, silicon nitride, silicon oxynitride, etc. A diameter D2 of each of the first bonding pads 312 may be within a range of about 40 μm to 400 μm.

In example embodiments, the substrate structure DS may include a dummy substrate layer 400 having a first surface 402 and a second surface 404 opposite to the first surface 402. The substrate structure DS may include a plurality of through electrodes (through silicon vias, TSVs) 450 that penetrate the dummy substrate layer 400. Additionally, the substrate structure DS may include a plurality of dummy through electrodes 460 that penetrate the dummy substrate layer 400. The plurality of through electrodes 450 and the plurality of dummy through electrodes 460 may extend from the first surface 402 to the second surface 404 of the dummy substrate layer 400.

As illustrated in FIG. 3, the dummy substrate layer 400 may cover a fan-in region where the semiconductor chip 200 may be disposed, and a fan-out region outside the region where the semiconductor chip 200 may be disposed. The fan-out region may surround the semiconductor chip 200 in a plan view. The plurality of through electrodes 450 may be provided to penetrate the dummy substrate layer 400 in the fan-in region, and the plurality of dummy through electrodes 460 may be provided to penetrate the dummy substrate layer 400 in the fan-out region. Additionally, a plurality of dummy through electrodes 460 may be provided in the fan-in region and the fan-out region. The plurality of dummy through electrodes 460 may extend from the first surface 402 of the dummy substrate layer 400 to a predetermined depth without penetrating the dummy substrate layer 400. A length L1 of one side (width in X direction or Y direction) of the semiconductor chip 200 may be within a range of about 1 mm to 50 mm, and a length L2 of one side (width in X direction or Y direction) of the dummy substrate layer 400 may be within a range of about 1 mm to 60 mm.

For example, the through electrodes 450 and the dummy through electrodes 460 may include copper (Cu). A diameter D3 of each of the through electrodes 450 and the dummy through electrodes 460 may be within a range of about 5 μm to 50 μm. The dummy substrate layer 400 may have a thickness H in a range of about 30 μm to 500 μm. The dummy substrate layer 400 may cover the fan-out region where relatively high warpage may occur, which may improve a warping of an edge region of the package. Accordingly, the thickness H of the dummy substrate layer 400 may affect the warpage of the entire package.

In example embodiments, the substrate structure DS may further include a second dielectric layer 410 provided on the first surface 402 of the dummy substrate layer 400. A plurality of second bonding pads 412 may be provided in the second dielectric layer 410 to be connected to end portions of the plurality of through electrodes 450 respectively.

The second bonding pads 412 may be electrically connected to the through electrodes 450. A lower surface of the second bonding pad 412 may be located on the same plane as a lower surface of the second dielectric layer 410. For example, the second dielectric layer 410 may include silicon oxide, silicon nitride, silicon oxynitride, etc. A diameter D2 of each of the second bonding pads 412 may be within a range of about 40 μm to 400 μm.

As illustrated in FIG. 2, the substrate structure DS may be bonded to the lower structure LS. The first dielectric layer 310 on the upper surface 302 of the sealing member 300 and the second dielectric layer 410 on the first surface 402 of the dummy substrate layer 400 may be bonded to each other by hybrid bonding. The first bonding pad 312 of the first dielectric layer 310 and the second bonding pad 412 of the second dielectric layer 410 may be bonded to each other by copper-copper hybrid bonding (Cu—Cu hybrid bonding).

The first dielectric layer 310 and the second dielectric layer 410 may include a dielectric material that contacts each other and provides excellent bonding strength, which may be used as a bonding structure. The first and second dielectric layers 310 and 410 may be bonded to each other by a high temperature annealing process while in contact with each other. Here, the bonding structure may have a relatively stronger bonding strength by covalent bonding.

The first bonding pads 312 and the second bonding pads 412 may include a same metal. For example, the metal may include copper (Cu). However, the present disclosure is not limited thereto, and the first and second bonding pads may include a material (e.g., gold (Au)) that can be bonded by inter-diffusion of metals by a high-temperature annealing process.

Accordingly, the plurality of through electrodes 450 may be electrically connected to the plurality of through vias 350 by the first bonding pads 312 and the second bonding pads 412.

In example embodiments, the upper redistribution wiring layer 500 as the upper structure US may disposed on the second surface 404 of the dummy substrate layer 400 and may include second redistribution wirings 502 electrically connected to the through electrodes 450 respectively. The second redistribution wirings 502 may include upper redistribution wirings stacked in at least two layers on the upper surface 404 of the dummy substrate layer 400. The second redistribution wirings 502 may be provided on the sealing member 300 to serve as backside redistribution wirings. Accordingly, the upper redistribution wiring layer 500 may be a backside redistribution wiring layer (BRDL) of the fan-out package.

The second redistribution wirings 502 may be electrically connected to the first redistribution wirings 102 through the through electrodes 450 and through vias 350. The second redistribution wirings 502 may include a first upper redistribution wiring 512 and a second upper redistribution wiring 522 stacked in two layers. In this case, the second upper redistribution wiring 522 may correspond to an uppermost redistribution wiring among the second redistribution wirings.

In particular, connection pads 422 may be provided on end portions of the through electrodes 450 exposed from thee second surface 404 of the dummy substrate layer 400. A first upper insulating layer 510 may be provided on the upper surface 404 of the dummy substrate layer 400 and may have openings that expose upper surfaces of the connection pads 422. The first upper redistribution wiring 512 may be formed on the first upper insulating layer 510 and at least portions of the first upper redistribution wiring 512 may directly contact the connection pads 422 through the openings.

A second upper insulating layer 520 may be provided on the first upper insulating layer 510 and may have openings that expose the first upper redistribution wiring 512. The second upper redistribution wiring 522 may be formed on the first upper insulating layer 510 and at least portions of the second upper redistribution wiring 512 may directly contact the first upper redistribution wiring 512 through the openings.

Although not illustrated in the figures, upper bonding pads may be respectively provided on the second upper redistribution wiring 522. A third upper insulating layer 530 may be provided on the second upper insulating layer 520 and may expose at least portions of the upper bonding pads. The third upper insulating layer 530 may serve as a passivation layer.

For example, the first, second and third upper insulating layers may include a polymer or a dielectric layer. The first, second and third upper insulating layers may include a photosensitive insulating material (PID) or an insulating film such as ABF. The second redistribution wirings may include copper (Cu), aluminum (Al), tin (Sn), nickel (Ni), gold (Au), platinum (Pt), or an alloy thereof.

The numbers and arrangements of the upper insulating layers and the upper redistribution wirings of the upper redistribution wiring layer are provided as examples, and it will be understood that the present disclosure is not limited thereto.

In example embodiments, the external connection members 160 may be disposed on the first connection pads 112 on the outer surface of the lower redistribution wiring layer 100. For example, the external connection member 160 may include a solder ball. The solder ball may have a diameter of 300 μm to 500 μm. The semiconductor package 10 may be mounted on a module substrate (not illustrated) via the solder balls to form a memory module.

As mentioned herein, the semiconductor package 10 as a fan-out wafer level package may include the lower redistribution wiring layer 100, the semiconductor chip 200 disposed on the lower redistribution wiring layer 100, the sealing member 300 covering at least a portion of the semiconductor chip 200 on the upper surface of the lower redistribution wiring layer 100 and having the plurality of through vias 350 that are provided to penetrate the sealing member 300, the dummy substrate layer 400 stacked on the upper surface 302 of the sealing member 300 and having the plurality of through electrodes 450 and the plurality of dummy through electrodes 460 that are provided to penetrate the dummy substrate layer 400, and the upper redistribution wiring layer 500 disposed on the dummy substrate layer 400.

The dummy substrate layer 400 may cover the fan-in region where the semiconductor chip 200 may be disposed and the fan-out region outside the region where the semiconductor chip 200 may be disposed. The plurality of through electrodes 450 may be provided to penetrate the dummy substrate layer 400 in the fan-in region, and the plurality of dummy through electrodes 460 may be provided to penetrate the dummy substrate layer 400 in the fan-out region.

The dummy substrate layer 400 may cover the fan-out region where relatively high warpage may occur, which may improve warping of the package. For example, the dummy substrate layer 400 may cover the fan-out region where relatively high warpage may occur, which may reduce or prevent warping of an edge region of the package. The dummy substrate layer 400 may serve as a heat spreader that spreads heat from the semiconductor chip 200, which may improve heat dissipation characteristics. The dummy through electrodes 460 may serve as heat dissipation passages to effectively dissipate heat from the semiconductor chip 200 to the outside, which may improve heat dissipation characteristics.

Hereinafter, a method of manufacturing the semiconductor package of FIG. 1 will be described.

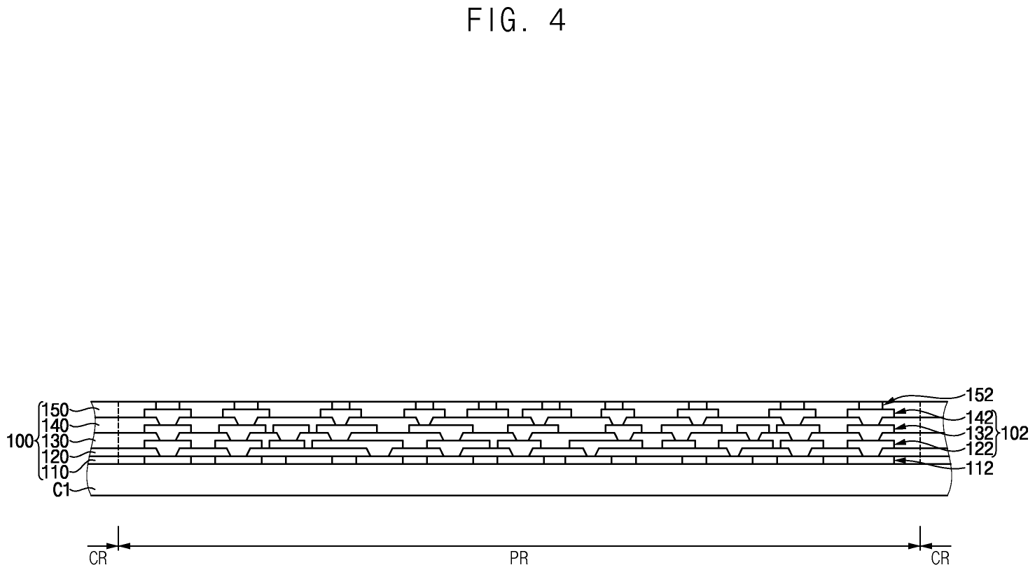

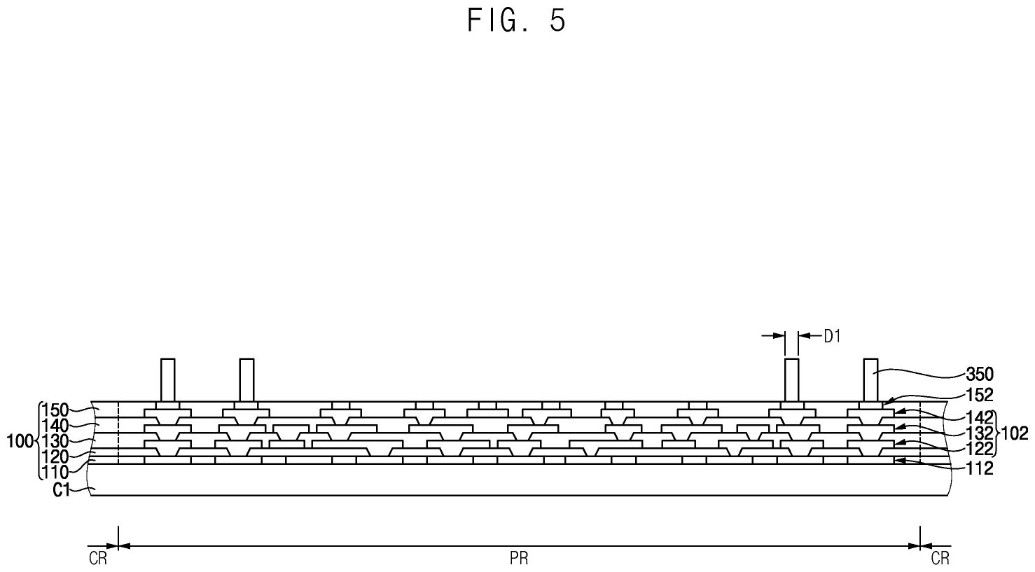

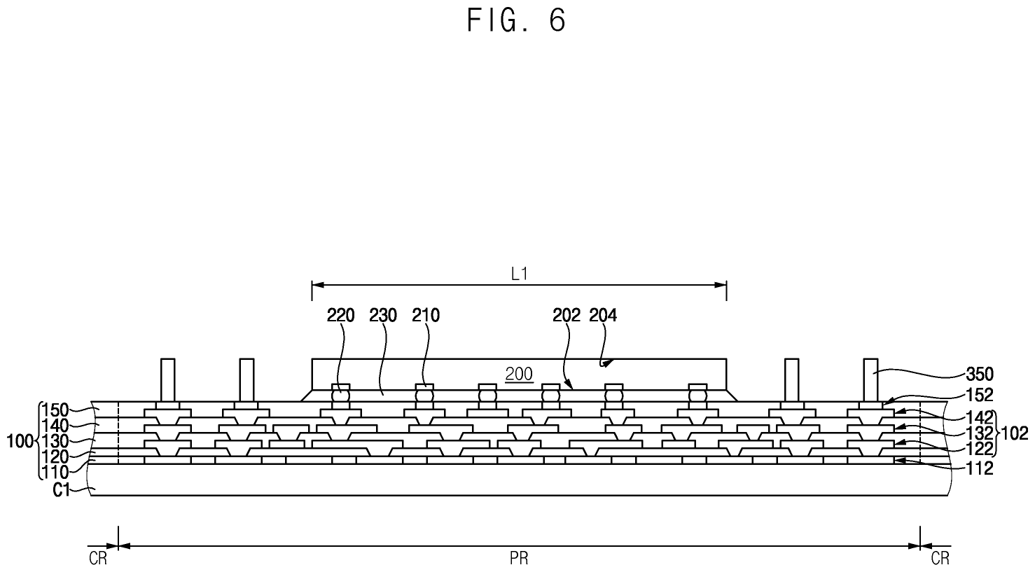

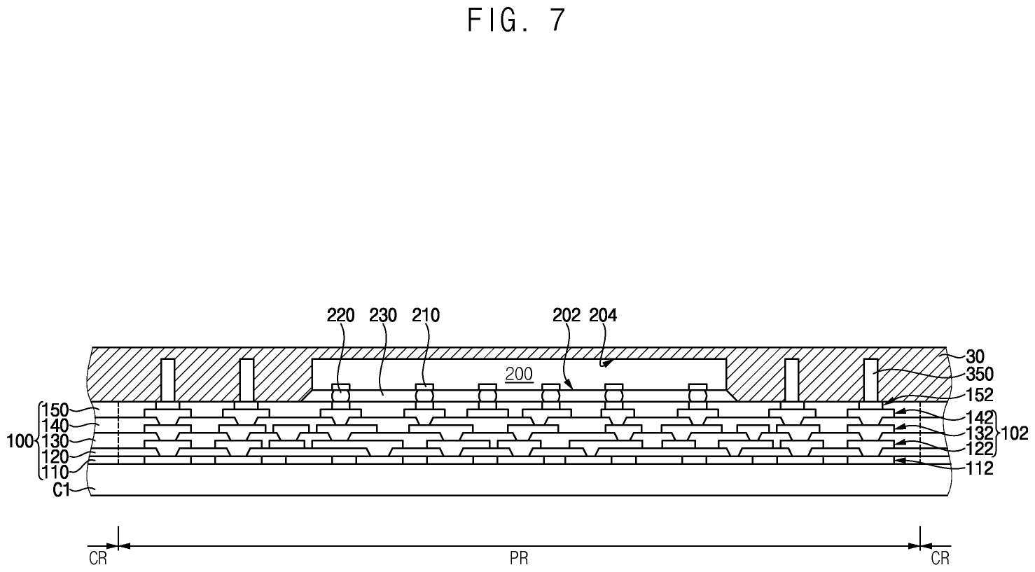

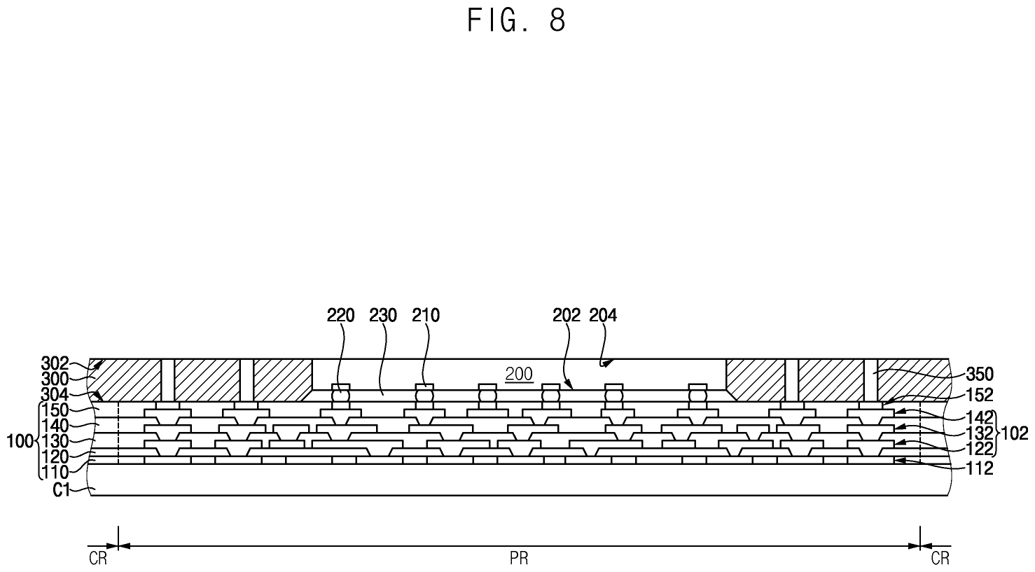

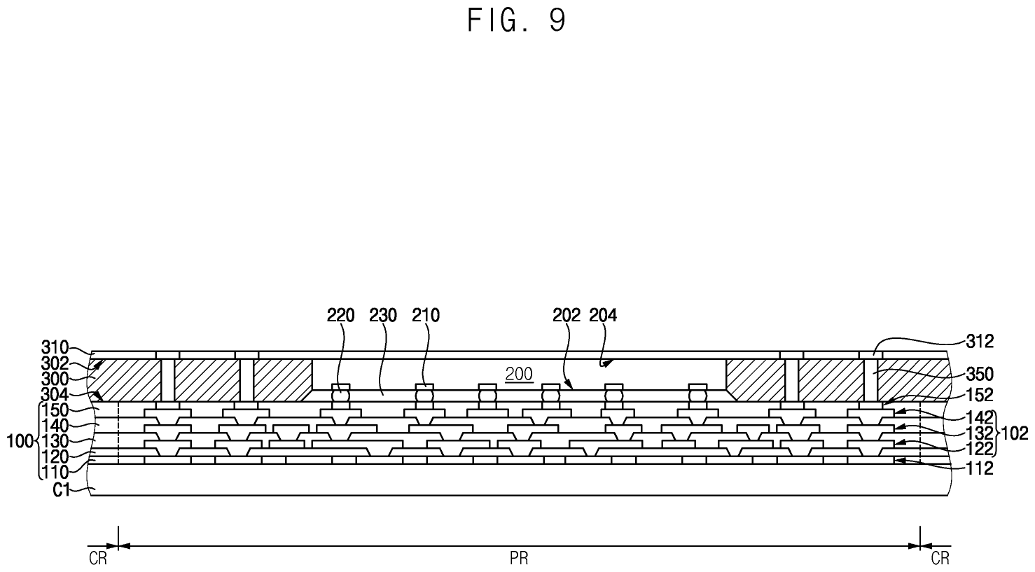

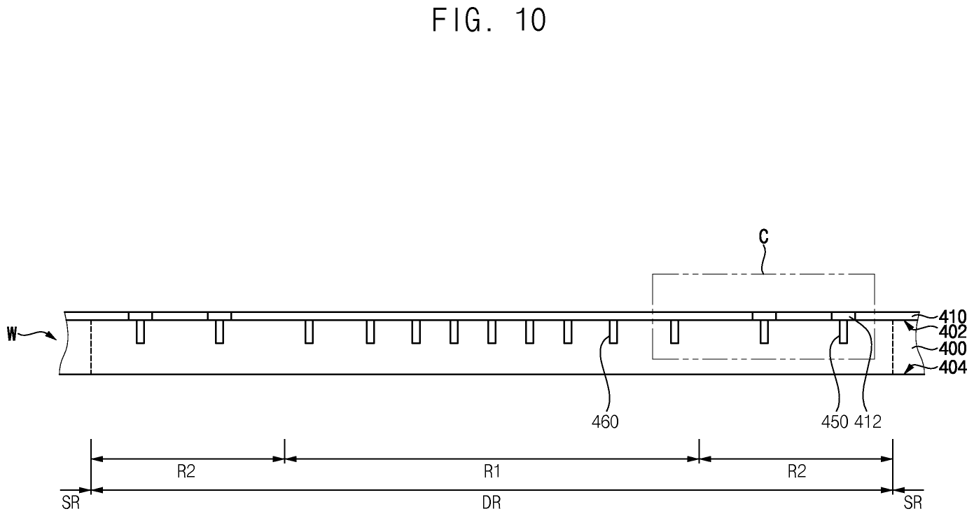

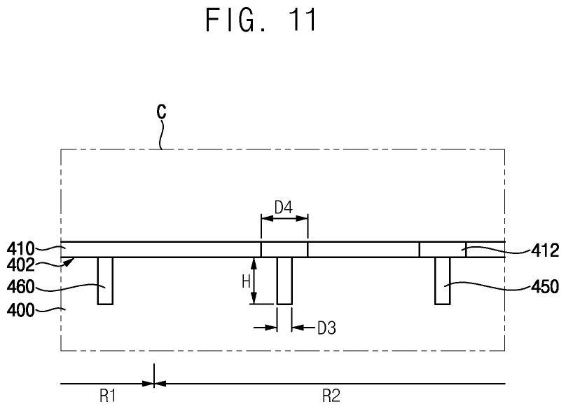

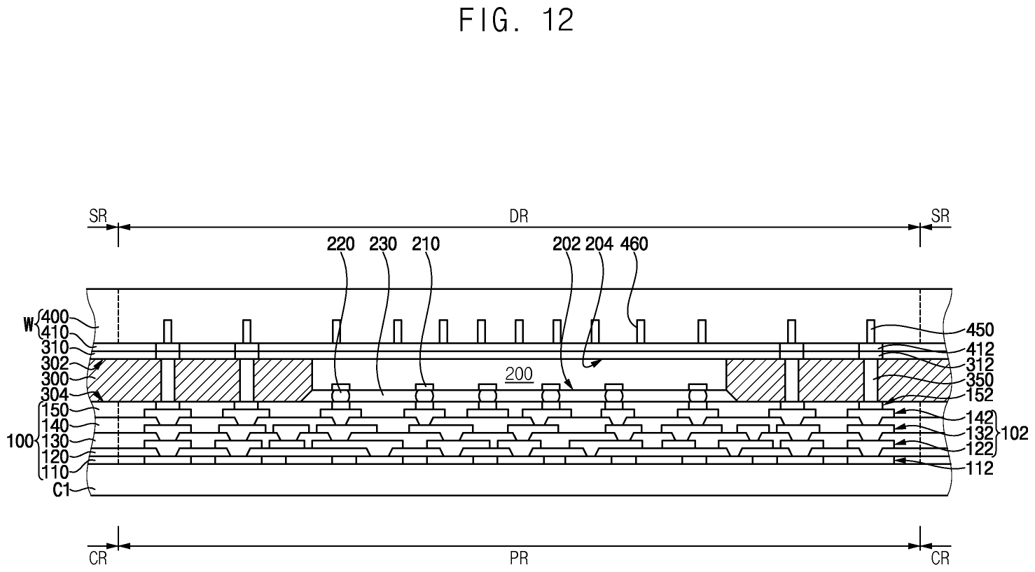

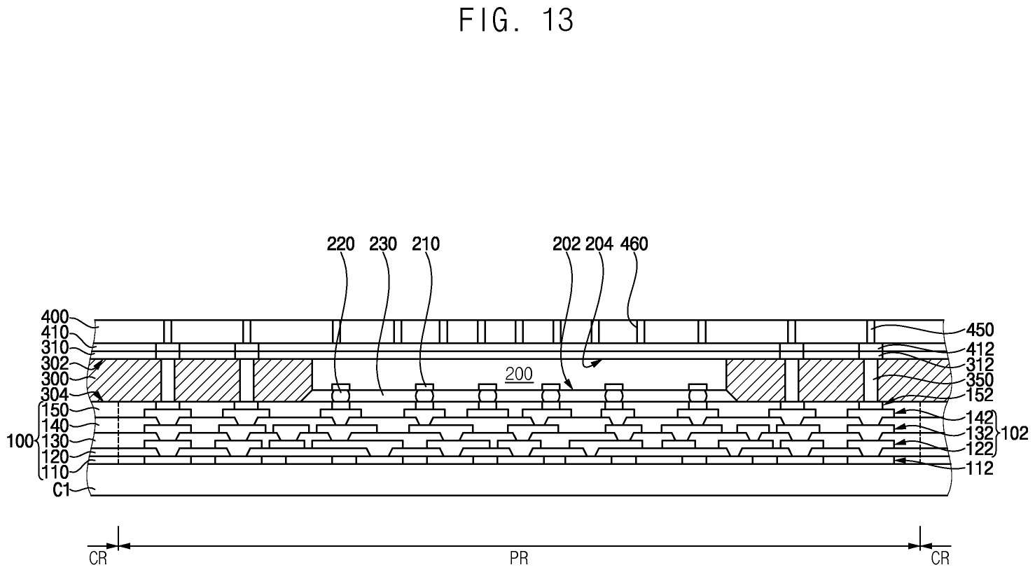

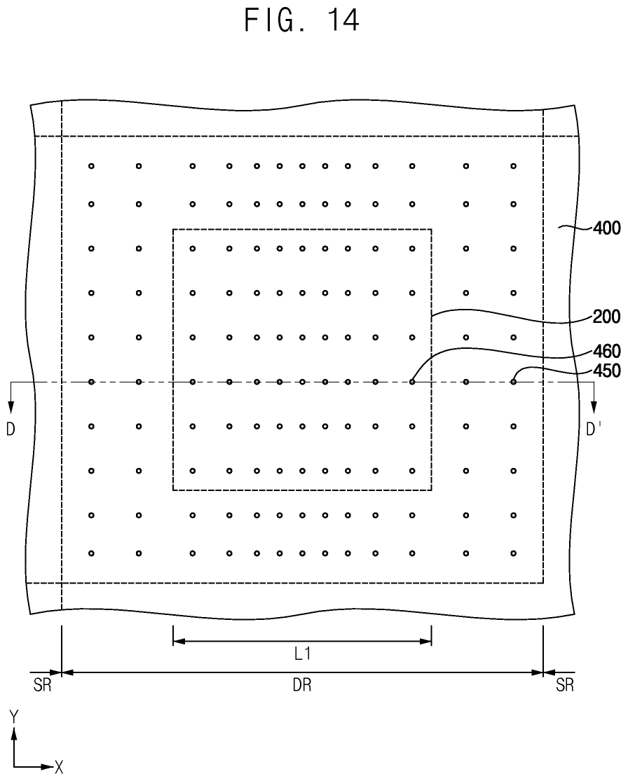

FIGS. 4 to 15 are views illustrating a method of manufacturing a semiconductor package in accordance with example embodiments. FIGS. 4 to 10, 12, 13 and 15 are cross-sectional views illustrating a method of manufacturing a semiconductor package in accordance with example embodiments. FIG. 11 is an enlarged cross-sectional view illustrating portion ‘C’ in FIG. 10. FIG. 14 is a plan view of FIG. 13. FIG. 13 is a cross-sectional view taken along the line D-D′ in FIG. 14.

Referring to FIG. 4, a lower redistribution wiring layer 100 having first redistribution wirings 102 as lower redistribution wirings may be formed on a first carrier substrate C1.

In example embodiments, the first carrier substrate C1 may include a wafer substrate as a base substrate on which a plurality of semiconductor chips may be disposed on the lower redistribution wiring layer and a sealing member may be formed to cover them. The first carrier substrate C1 may have a shape corresponding to a wafer on which a semiconductor process may be performed. For example, the first carrier substrate C1 may include a silicon substrate, a glass substrate, a non-metal or metal plate, etc.

The first carrier substrate C1 may include a package region PR on which the semiconductor chip may be mounted and a cutting region CR surrounding the package region PR. As described herein, the lower redistribution wiring layer 100 and the sealing member formed on the first carrier substrate C1 may be cut along the cutting region CR that divides the plurality of package regions MR to be individualized.

In particular, a plating process may be performed on the first carrier substrate C1 to form a first lower insulating layer 110 including first connection pads 112 formed therein. Although not illustrated in the figures, after sequentially forming a release film, a barrier metal layer, a seed layer and the first lower insulating layer on the first carrier substrate C, the first lower insulating layer may be patterned to form openings that expose first connection pad regions. The plating process may be performed on the seed layer to form the first connection pads 112 in the openings.

For example, the first lower insulating layer 110 may include a polymer or a dielectric layer. The first lower insulating layer 110 may include a photosensitive insulating material (PID) or an insulating film such as ABF. The first lower insulating layer may be formed by a spin coating process, a vapor deposition process, etc.

When the first lower insulating layer includes the photosensitive insulating material such as PID, after a barrier metal layer, a seed layer and the photosensitive insulating layer are formed on the first carrier substrate C, the photosensitive insulating layer may be patterned to form preliminary openings that expose the first connection pad regions. The photosensitive insulating layer may be patterning by performing an exposure process and a development process. A curing process of the photosensitive insulating layer may be performed such that a portion of the photosensitive insulating layer flows down toward the preliminary opening to form a tapered opening. A plating process may be performed to form the first connection pad in the tapered opening of the photosensitive insulating layer.

In this case, the first connection pad may have a shape corresponding to the tapered opening. A diameter of a lower surface of the first connection pad may be greater than a diameter of an upper surface of the first connection pad. A sidewall of the opening may have a first angle with respect to a lower surface of the photosensitive insulating layer. The first angle may be an obtuse angle range of about 100 degrees to 135 degrees. Accordingly, a sidewall of the first connection pad may be inclined to have an acute angel of about 45 degrees to 80 degrees with respect to the lower surface of the photosensitive insulating layer.

The first connection pad 112 may be a bump pad. The bump pad may include a solder pad or a pillar pad. For example, the first connection pad may include copper (Cu), aluminum (Al), tin (Sn), nickel (Ni), gold (Au), platinum (Pt), or an alloy thereof.

After a second lower insulating layer 120 is formed on the first lower insulating layer 110 to cover the first connection pads 112, the second lower insulating layer 120 may be patterned to form first openings that expose at least portions of the first connection pads 112.

For example, the second lower insulating layer 120 may include a polymer or a dielectric layer. The second lower insulating layer 120 may include a photosensitive insulating material (PID) or an insulating film such as ABF. The second lower insulating layer may be formed by a spin coating process, a vapor deposition process, etc.

When the second lower insulating layer includes a photosensitive insulating material, the second lower insulating layer may be patterned by an exposure process and a developing process to form a preliminary opening. A curing process of the second lower insulating layer may be performed such that a portion of the second lower insulating layer flows down toward the preliminary opening to form a tapered first opening. In this case, a diameter of a lower surface of the first opening may be greater than a diameter of an upper surface of the first opening, and a sidewall of the first opening may be inclined to have an acute angle of 45 degrees to 80 degrees with respect to a lower surface of the second lower insulating layer.

First lower redistribution wiring 122 may be formed on the second lower insulating layer 120. The first lower redistribution wiring 122 may be electrically connected to the first connection pads 112 through the first openings of the second lower insulating layer 120.

In example embodiments, a barrier layer and a seed layer may be sequentially formed on the second lower insulating layer 120. The barrier layer may be formed on a sidewall of the first opening 121 of the second lower insulating layer 120 and a portion of the first connection pad 112 exposed by the first opening.

For example, the barrier layer may include titanium, titanium nitride, tantalum, tantalum nitride, tungsten, etc. The seed layer may include copper, gold, silver, aluminum, or an alloy thereof. The barrier layer and the seed layer may be formed by a physical vapor deposition method or the like. The barrier layer may have a thickness of about 500 angstrom (Å) to about 2,000 Å. The seed layer 123 may have a thickness of about 500 Å to about 1,500 Å.

A photoresist layer may be formed on the seed layer, and an exposure process and a development process may be performed on the photoresist layer to form a photoresist pattern having an openings that expose first lower redistribution regions. A first plating pattern may be formed in the opening of the photoresist pattern, and the photoresist pattern may be removed from the second lower insulating layer. The first plating pattern may be formed by an electroplating process or an electroless plating process.

A portion of the seed layer exposed by the first plating pattern may be removed to form a first seed layer pattern. The portion of the seed layer exposed by the first plating pattern may be removed by an isotropic etching process. The portion of the seed layer may be removed by a wet etching process.

A portion of the barrier layer exposed by the first seed layer pattern may be removed to form a first barrier layer pattern. A portion of the barrier layer exposed by the first plating pattern may be removed by an anisotropic etching process. The portion of the barrier layer may be removed by a dry etching process.

Thus, the first lower redistribution wiring 122 including the first barrier layer pattern, the first seed layer pattern and the first plating pattern may be formed on the second lower insulating layer 120. The first lower redistribution wiring 122 may be electrically connected to the first connection pad 112 through the first opening of the second lower insulating layer 120.

Similarly, a third lower insulating layer 130 may be formed on the second lower insulating layer 120 to cover the first lower redistribution wirings 126 and the third lower insulating layer 130 may be patterned to form second openings that expose at least portions of the first lower redistribution wiring 122. Second lower redistribution wiring 132 may be formed on the third lower insulating layer 130. The second lower redistribution wiring 132 may be electrically connected to the first lower redistribution wiring 122 through the second openings.

A fourth lower insulating layer 140 may be formed on the third lower insulating layer 130 to cover the second lower redistribution wiring 132 and the fourth lower insulating layer 140 may be patterned to form third openings that expose at least portions of the second lower redistribution wiring 132. Third lower redistribution wiring 142 may be formed on the fourth lower insulating layer 140. The third lower redistribution wiring 142 may be electrically connected to the second lower redistribution wiring 132 through the third openings.

Second connection pads 152 may be formed on the third lower redistribution wiring 142. A solder resist layer 150 as a fifth lower insulating layer may be formed on the fourth lower insulating layer 140 to cover the third redistribution wirings 146 and expose at least portions of the second connection pads 152.

Thus, the lower redistribution wiring layer 100 having the first to fifth lower insulating layers 110, 120, 130, 140 and 150 may be formed. The lower redistribution wiring layer 100 may be a front redistribution wiring layer (FRDL) of a fan-out package. The second connection pads 152 may be exposed from an upper surface of the lower redistribution wiring layer 100.

Referring to FIG. 5, a plurality of through vias 350 as conductive structures may be formed on the upper surface of the lower redistribution wiring layer 100.

In example embodiments, a photoresist layer may be formed on the upper surface of the lower redistribution wiring layer 100, and an exposure process may be performed on the photoresist layer to form a photoresist pattern having openings that are provided in a fan-out region of the lower redistribution wiring layer 100 for forming the plurality of through vias. The opening may expose at least a portion of the second connection pad 152 in the fan-out region.

An electro plating process may be performed to fill the openings of the photoresist pattern with a conductive material to form the through vias 350. The photoresist pattern may be removed by a strip process.

The through vias 350 as conductive connection structures may extend upward from the second bonding pad 152. The through vias 350 may be electrically connected to the first redistribution wirings 102. As described herein, the through via 350 may be provided to penetrate the sealing member and to serve as an electrical connector. That is, the through vias 350 may be provided in the fan-out region outside of an area where a semiconductor chip (die) may be disposed and may be used for electrical connection. For example, a diameter D1 of each of the through vias 350 may be within a range of about 30 micrometers (μm) to 300 μm.

Referring to FIG. 6, at least one semiconductor chip 200 may be mounted in a fan-in region on the upper surface of the lower redistribution wiring layer 100.

In example embodiments, the semiconductor chip 200 may be mounted on the upper surface of the lower redistribution wiring layer 100 by a flip chip bonding method. The semiconductor chip 200 may be disposed such that a front surface 202 on which chip pads 210 are formed, that is, an active surface faces the lower redistribution wiring layer 100. The chip pads 210 of the semiconductor chip 200 may be electrically connected to the second connection pads 152 of the lower redistribution wiring layer 100 by conductive bumps 220. Accordingly, the semiconductor chip 200 may be electrically connected to the first redistribution wirings 102 of the lower redistribution wiring layer 100 by the conductive bumps 220.

For example, the conductive bump 220 may include a micro bump (uBump). A length L1 of one side of the semiconductor chip 200 may be within a range of about 1 millimeters (mm) to 50 mm.

An underfill member 230 may be underfilled between the semiconductor chip 200 and the lower redistribution wiring layer 100. The underfill member may include a material having relatively high fluidity to effectively fill a small space between the semiconductor chip and the lower redistribution wiring layer. For example, the underfill member may include an adhesive containing an epoxy material.

The semiconductor chip may be a logic chip including a logic circuit. The logic chip may be a controller that controls memory chips. The semiconductor chip may be a processor chip such as an ASIC or an application processor (AP) serving as a host such as a CPU, GPU, or SOC.

Referring to FIG. 7, a sealing material 30 may be formed on the upper surface of the lower redistribution wiring layer 100 to cover the semiconductor chip 200 and the plurality of through vias 350.

The sealing material 30 may be formed to cover an upper surface 204 of the semiconductor chip 200 and upper surfaces of the plurality of through vias 350. For example, the sealing material 30 may include an epoxy molding compound (EMC). The sealing material 30 may include UV resin, polyurethane resin, silicone resin, silica filler, etc.

Referring to FIG. 8, an upper portion of the sealing material 30 may be partially removed to form a sealing member 300 that exposes the upper surfaces of the plurality of through vias 350. The upper portion of the sealing material 30 may be partially removed by a grinding process. The sealing member 300 may cover the upper surface of the lower redistribution wiring layer 100 around the semiconductor chip 200. The sealing member 300 may expose the upper surface 204 of the semiconductor chip 200. Alternatively, the sealing member 300 may cover the upper surface of the semiconductor chip 200.

Accordingly, the plurality of through vias 350 may be formed on the upper surface of the fan-out region of the lower redistribution wiring layer 100 and may extend to penetrate the sealing member 300. The through via 350 may be a through mold via (TMV) formed to penetrate the sealing member 300.

Referring to FIG. 9, a first dielectric layer 310 including a plurality of first bonding pads 312 formed therein may be formed on an upper surface 302 of the sealing member 300.

In example embodiments, after the first dielectric layer 310 is formed on the upper surface 302 of the sealing member 300, the first dielectric layer 310 may be patterned to form openings that expose end portions of the through vias 350 respectively. The openings of the patterned first dielectric layer 310 may expose upper surfaces of the through vias 350. For example, the first dielectric layer 310 may include silicon oxide, silicon nitride, silicon oxynitride, etc.

After a seed layer is formed on portions of the exposed through vias 350 and in the openings, the seed layer may be patterned, and an electroplating process may be performed to form the first bonding pads 312. Accordingly, the first bonding pads 312 may be electrically connected to the through vias 350 through the openings. An upper surface of the first bonding pad 312 may be located on the same plane as an upper surface of the first dielectric layer 310. For example, a diameter D2 of each of the first bonding pads 312 may be within a range of about 40 μm to 400 μm.

Referring to FIGS. 10 and 11, a wafer W including a plurality of through electrodes 450 formed therein may be provided.

In example embodiments, the wafer W may include a dummy substrate layer 400 having a first surface 402 and a second surface 404 opposite the first surface 402. The wafer W may include a die region DA and a scribe lane region SA surrounding the die region DA. As described herein, the die region DA may correspond to the package region MR of the first carrier substrate C1, and the scribe lane region SA may correspond to the cutting region CR of the first carrier substrate C1. As described herein, the wafer W may be cut along the scribe lane region SA that divides the plurality of die regions DA of the wafer W by a following sawing process to be individualized into a plurality of substrate structures.

For example, the dummy substrate layer 400 may include a semiconductor material such as silicon, germanium, silicon-germanium, or a group III-V compound semiconductor such as gallium phosphide (GaP), gallium arsenide (GaAs), or gallium antimonide (GaSb).

The wafer W may include a plurality of through electrodes (through silicon vias, TSVs) 450 that may partially penetrate the dummy substrate layer 400. The wafer W may further include a plurality of dummy through electrodes 460 that partially penetrate the dummy substrate layer 400. The through electrodes 450 and the dummy through electrodes 460 may extend from the first surface 402 of the dummy substrate layer 400 to a predetermined depth H, respectively.

The plurality of through electrodes 450 may be provided in a first area R1 in the die region DA, and the plurality of dummy through electrodes 460 may be provided in the second region R2 in the die region DA. The first region R1 may correspond to the fan-in region where the semiconductor chip 200 may be disposed, and the second region R2 may correspond to the fan-out region outside the region where the semiconductor chip 200 may be disposed. For example, the through electrodes 450 and the dummy through electrodes 460 may include copper (Cu). A diameter D3 of each of the through electrodes 450 and the dummy through electrodes 460 may be within a range of about 5 μm to 50 μm.

In example embodiments, a second dielectric layer 410 including a plurality of second bonding pads 412 formed therein may be formed on the first surface 402 of the dummy substrate layer 400 of the wafer W.

In example embodiments, after the second dielectric layer 410 is formed on the first surface 402 of the dummy substrate layer 400, the second dielectric layer 410 may be patterned to form openings that expose end portions of the through electrodes 450. The openings of the patterned second dielectric layer 410 may expose upper surfaces of the through electrodes 450 respectively. For example, the second dielectric layer 410 may include silicon oxide, silicon nitride, silicon oxynitride, etc.

After a seed layer is formed on portions of the exposed through electrodes 450 and in the openings, the seed layer may be patterned, and an electro plating process may be performed to form the second bonding pads 412. Accordingly, the second bonding pads 412 may be electrically connected to the through electrodes 450 through the openings. An upper surface of the second bonding pad 412 may be located on the same plane as an upper surface of the second dielectric layer 310. For example, a diameter D4 of each of the second bonding pads 412 may be within the range of about 40 μm to 400 μm.

Referring to FIG. 12, the wafer W of FIG. 10 may be attached to the sealing member 300 of the lower structure of FIG. 9 (wafer-to-wafer hybrid bonding process).

In example embodiments, the wafer W of FIG. 10 may be bonded to the sealing member 300 on the first carrier substrate C1. The wafer W may be stacked on the sealing member 300 of the lower structure such that the first surface 402 of the dummy substrate layer 400 of the wafer W faces the upper surface 302 of the sealing member 300. The wafer W may be placed on the sealing member 300 such that the die region DR of the wafer W corresponds to the package region PR and the scribe lane region DR of the wafer W corresponds to the cutting region CR.

When the sealing member 300 on the first carrier substrate C1 and the dummy substrate layer 400 on the wafer W are bonded to each other by wafer-to-wafer bonding, the first dielectric layer 310 on the upper surface 302 of the sealing member 300 and the second dielectric layer 410 on the first surface 402 of the dummy substrate layer 400 of the wafer W may be hybrid-bonded to each other by a thermal compression process and an annealing process. That is, first dielectric layer on the upper surface 302 of the sealing member 300 may be directly bonded to the second dielectric layer 410 on the first surface 402 of the dummy substrate layer 400 of the wafer W, and the first bonding pad 312 and the second bonding pad 412 may be bonded to each other by copper-copper hybrid bonding (Cu—Cu Hybrid Bonding).

The first dielectric layer 310 and the second dielectric layer 410 may include a dielectric material that contacts each other and provides excellent bonding strength, which may be used as a bonding structure. The first dielectric layer 310 and second dielectric layer 410 may be bonded to each other by a high temperature annealing process while in contact with each other. Here, the bonding structure may have a relatively strong bonding strength by covalent bonding.

The first bonding pads 312 and the second bonding pads 412 may include a same metal. For example, the metal may include copper (Cu). However, the present disclosure is not limited thereto, and the first and second bonding pads may include a material (e.g., gold (Au)) that can be bonded by inter-diffusion of metals by a high-temperature annealing process.

Referring to FIG. 13 and FIG. 14, a backside surface of the wafer W, which may be the second surface 404 of the dummy substrate layer 400, may be partially removed to expose end portions of the through electrodes 450. Here, end portions of the dummy through electrodes 460 may be exposed together with the end portions of the through electrodes 450. Alternatively, when the dummy through electrodes 460 have lengths less than lengths of the through electrodes 450, the end portions of the dummy through electrodes 460 may not be exposed.

For example, the second surface 404 of the dummy substrate layer 400 may be grinded by a grinding process. Since the grinding process may be performed at the wafer level, the entire second surface 404 of the dummy substrate layer 400 may be reduced to a uniform thickness. Accordingly, the dummy substrate layer 400 may be reduced to a desired thickness. For example, the dummy substrate layer 400 may have a thickness in a range of about 30 μm to 500 μm. The dummy substrate layer 400 may cover the fan-out region where relatively high warpage may occur, which may improve warping of an edge region of the package. Accordingly, the thickness of the dummy substrate layer 400 may be affect the warpage of the entire package.

Referring to FIG. 15, an upper redistribution wiring layer 500 having second redistribution wirings 502 may be formed on the second surface 404 of the dummy substrate layer 400. The second redistribution wirings 502 as upper redistribution wirings may be electrically connected to the through electrodes 450.

In example embodiments, connection pads 422 may be formed on the exposed end portions of the through electrodes 450 on the second surface 404 of the dummy substrate layer 400. After a first upper insulating layer 510 is formed on the second surface 404 of the dummy substrate layer 400, the first upper insulating layer 510 may be patterned to form openings that expose the connection pads 422, respectively. The openings in the patterned first upper insulating layer 510 may expose the connection pads 422. Alternatively, the process of forming the connection pads may be omitted. In this case, the openings of the patterned first upper insulating layer 510 may expose the exposed end portions of the through electrodes 450.

After a seed layer is formed on portions of the exposed connection pads 422 and in the openings, the seed layer may be patterned, and an electrolytic plating process may be performed to form first upper redistribution wiring 512. Accordingly, at least portions of the first upper redistribution wiring 512 may be electrically connected to the connection pads 422 through the openings.

After a second upper insulating layer 520 is formed on the first upper insulating layer 510, the second upper insulating layer 520 may be patterned to form openings that expose the first upper redistribution wiring 512. Second upper redistribution wiring 522 may be formed on the second upper insulating layer 520 to be electrically connected to the first upper redistribution wiring 512 through the openings.

Accordingly, the second redistribution wirings 502 may include the first upper redistribution wiring 512 and the second upper redistribution wiring 522 in stacked in two layers. In this case, the second upper redistribution wiring 522 may correspond to an uppermost redistribution wiring among the second redistribution wirings 502.

Upper bonding pads (not shown) may be formed on the second upper redistribution wiring 522 as the uppermost redistribution wirings, respectively, and a third upper insulating layer 530 may be formed on the second upper insulating layer 520 to expose at least portions of the upper bonding pads on the second upper redistribution wiring 522. The third upper insulating layer 530 may function as a passivation layer.

Thus, the upper redistribution wiring layer 500 having the first upper insulating layer 510, the second upper insulating layer 520, and the third upper insulating layer 530 may be formed. The upper redistribution wiring layer 500 may be a backside redistribution wiring layer (BRDL) of the fan-out package. The upper bonding pads may be exposed from an upper surface of the upper redistribution wiring layer 500.

External connection members 160 (see FIG. 1) may be formed on the first connection pads 112 on an outer surface, that is, the lower surface of the lower redistribution wiring layer 100 to be electrically connected to the first redistribution wirings 102 respectively.

A sawing process may be performed to divide the lower redistribution wiring layer 100 and complete a fan-out wafer level package 10 of FIG. 1 including the sealing member 300, the lower redistribution wiring layer 100 formed on the lower surface 304 of the sealing member 300, the substrate structure DS formed on the upper surface 302 of the sealing member 300, and the upper redistribution wiring layer 500 formed on the substrate structure DS.

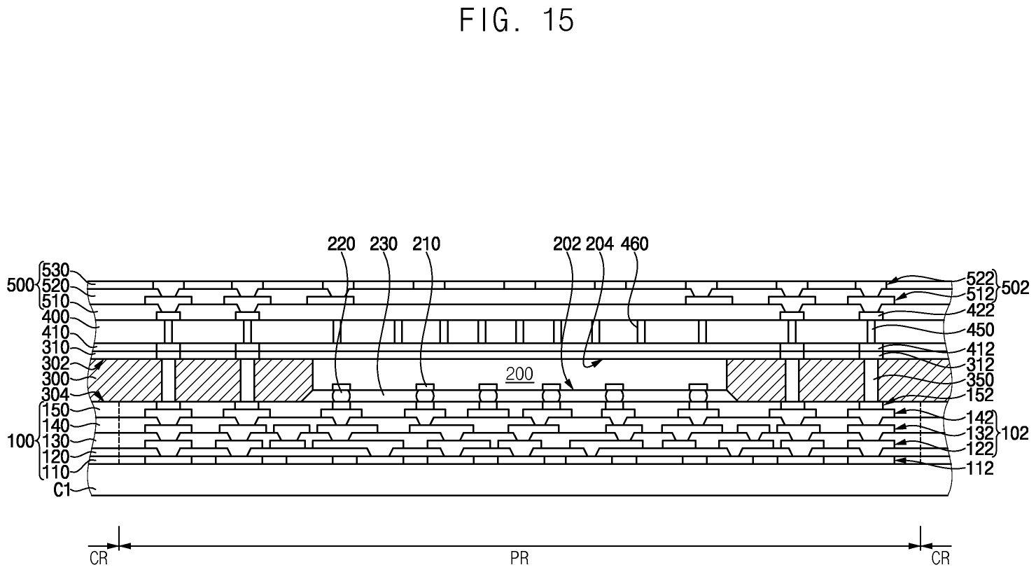

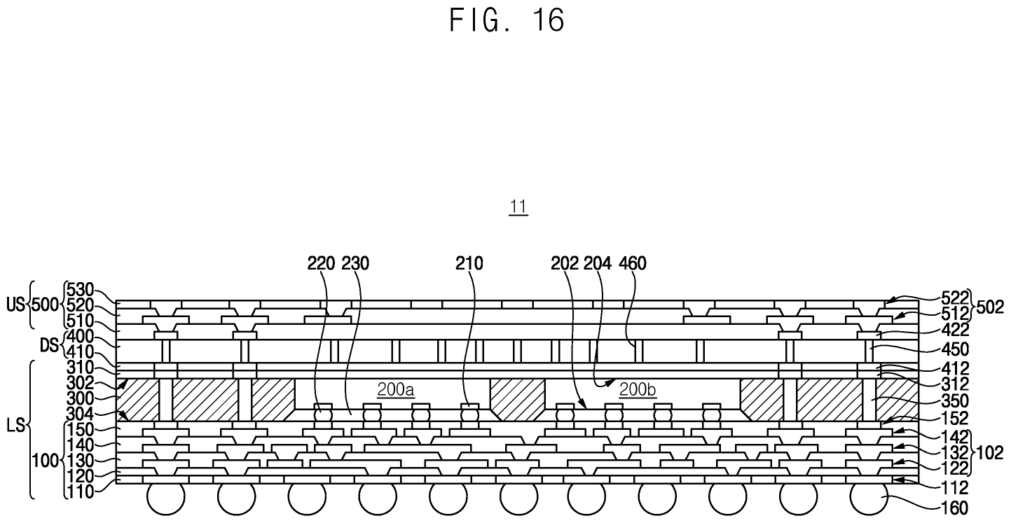

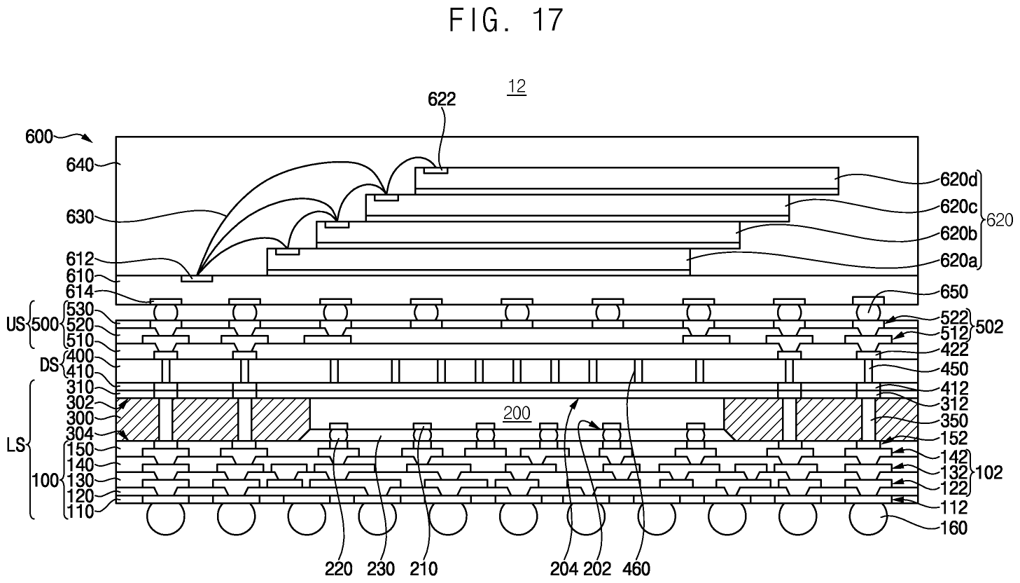

FIG. 16 is a cross-sectional view illustrating a semiconductor package in accordance with example embodiments. The semiconductor package may be substantially the same as the semiconductor package described with reference to FIG. 1 except for first semiconductor chips. Thus, same reference numerals may be used to refer to the same or like elements and any further repetitive explanation concerning the above elements may be omitted.

Referring to FIG. 16, a lower structure LS of a semiconductor package 11 may include multiple semiconductor chips disposed on a lower redistribution wiring layer 100.

In example embodiments, two semiconductor chips 200a and 200b may be arranged on an upper surface of the lower redistribution wiring layer 100 to be spaced apart from each other. The semiconductor chips 200a and 200b may be mounted respectively on the lower redistribution wiring layer 100 using a flip chip bonding method. The semiconductor chips 200a and 200b may be mounted on the lower redistribution wiring layer 100 via conductive bumps 220.

A sealing member 300 may cover at least portions of the semiconductor chips 200a and 200b on the upper surface of the lower redistribution wiring layer 100. The sealing member 300 may expose upper surfaces 204 of the semiconductor chips 200a and 200b, respectively. Alternatively, the sealing member 300 may be formed to cover the upper surfaces 204 of the semiconductor chips 200a and 200b.

A plurality of through vias 350 may be provided in a fan-out region outside a region where the semiconductor chips 200a and 200b are disposed, to electrically connect the lower redistribution wiring layer 100 and an upper redistribution wiring layer 500.

In example embodiments, a dummy substrate layer 400 of the substrate structure DS may cover a fan-in area where the semiconductor chips 200a and 200b are disposed, and the fan-out region outside the region where the semiconductor chips 200a and 200b are disposed. A plurality of through electrodes 450 may be provided to penetrate the dummy substrate layer 400 in the fan-in region, and a plurality of dummy through electrodes 460 may be provided to penetrate the dummy substrate layer 400 in the fan-out region.

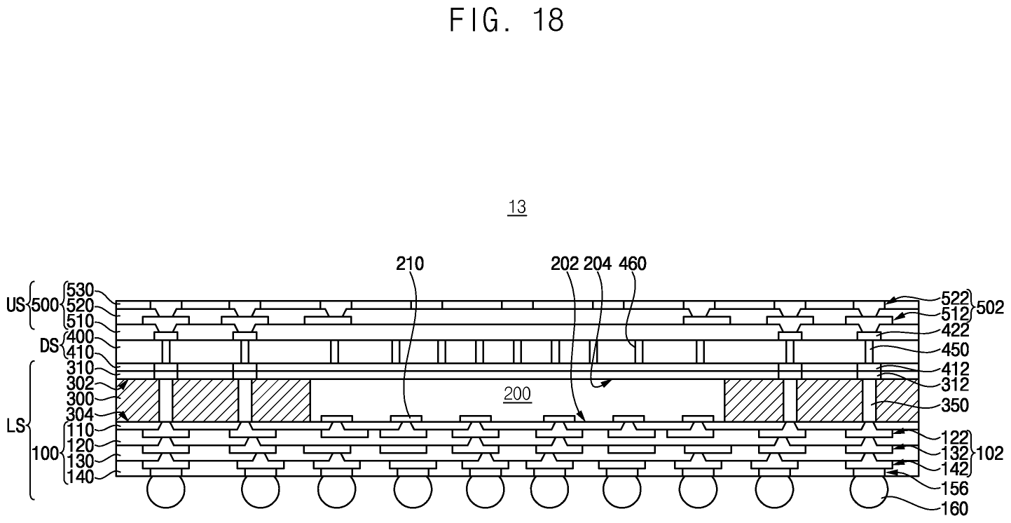

FIG. 17 is a cross-sectional view illustrating a semiconductor package in accordance with example embodiments. The semiconductor package may be substantially the same as the semiconductor package described with reference to FIG. 1 except for an additional second package. Thus, same reference numerals may be used to refer to the same or like elements and any further repetitive explanation concerning the above elements may be omitted.

Referring to FIG. 17, a semiconductor package 12 may include a first package and a second package 600 stacked on the first package. The first package may include a lower redistribution wiring layer 100, a semiconductor chip 200, a sealing member 300, a dummy substrate layer 400 and an upper redistribution wiring layer 500. The first package may be substantially the same as, or similar to, the unit package described with reference to FIG. 1.

In example embodiments, the second package 600 may include a second package substrate 610, a plurality of second semiconductor chips 620 mounted on the second package substrate 610 and a sealing member 640 covering the second semiconductor chips 620 on the second package substrate 610.

The second package 600 may be stacked on the first package via conductive connection members 650. For example, the conductive connection members 650 may include solder balls, conductive bumps, etc. The conductive connection member 650 may be disposed between an upper bonding pad on a second upper redistribution wiring 522 of the upper redistribution wiring layer 500 and a second connection pad 614 of the second package substrate 610. Accordingly, the first package and the second package 600 may be electrically connected to each other by the conductive connection members 650.

The plurality of second semiconductor chips 620a, 620b, 620c and 620d may be sequentially stacked on the second package substrate 610 by adhesive members. Bonding wires 630 may connect second chip pads 622 of the second semiconductor chips 620 to first connection pads 612 of the second package substrate 610. The second semiconductor chips 620 may be electrically connected to the second package substrate 610 through the bonding wires 630.

Although the second package 600 is illustrated as including four semiconductor chips mounted by a wire bonding method, it will be understood that the numbers of the semiconductor chips in the second package and the mounting method are not limited thereto.

Although not illustrated in the figure, a heat sink may be provided on the second package 600 to dissipate heat from the first and second packages to the outside. The heat sink may be attached on the second package 600 by using a thermal interface material (TIM).

FIG. 18 is a cross-sectional view illustrating a semiconductor package in accordance with example embodiments. The semiconductor package may be substantially the same as the semiconductor package described with reference to FIG. 1 except for a configuration of a lower structure. Thus, same reference numerals may be used to refer to the same or like elements and any further repetitive explanation concerning the above elements may be omitted.

Referring to FIG. 18, a semiconductor package 13 may include a lower structure LS, a substrate structure DS bonded to the lower structure LS, and an upper redistribution wiring layer 500. The lower substructure LS may include a lower redistribution wiring layer 100, a semiconductor chip 200 disposed on the lower redistribution wiring layer 100, and a sealing member 300 covering at least a portion of the semiconductor chip 200 on an upper surface of the lower redistribution wiring layer 100. In addition, the semiconductor package 10 may further include external connection members 160 disposed on an outer surface of the lower redistribution wiring layer 100.

In example embodiments, the semiconductor chip 200 may have a plurality of chip pads 210 on a front surface 202, that is, an active surface. The semiconductor chip 200 may be provided in the sealing member 300 such that the front surface 202 on which the chip pads 210 are formed faces the lower redistribution wiring layer 100. The sealing member 300 may cover an outer side surface of the semiconductor chip 200. The front surface 202 of the semiconductor chip 200 may be exposed from a lower surface 304 of the sealing member 300, and an upper surface 204 opposite to the front surface 202 of the semiconductor chip 200 may be exposed from an upper surface 302 of the sealing member 300.

A plurality of through vias 350 may extend in a vertical direction to penetrate the sealing member 300. One end portion of the through via 350 may be exposed from the upper surface 302 of the sealing member 300 and the other end portion of the through via 350 may be exposed from the lower surface 304 of the sealing member 300.

In example embodiments, the lower redistribution wiring layer 100 may be disposed on the lower surface 304 of the sealing member 300 and the front surface 202 of the semiconductor chip 200. The lower redistribution wiring layer 100 may include a plurality of first redistribution wirings 102. The first redistribution wirings 102 may be electrically connected to the chip pads 210 and the through vias 350 of the semiconductor chip 200, respectively. The first redistribution wirings 102 may be provided on the front surface 202 of the semiconductor chip 200 and the lower surface 304 of the sealing member 300 to serve as front redistribution wirings. Accordingly, the lower redistribution wiring layer 100 may be a front redistribution wiring layer of the fan-out package.

For example, the lower redistribution wiring layer 100 may include first, second, third and fourth lower insulating layers 110, 120, 130 and 140 sequentially stacked on the lower surface 304 of the sealing member 300. The first redistribution wirings 102 may include first, second and third lower redistribution wirings 122, 132 and 142 stacked in at least three layers.

The first lower insulating layer 110 may be formed on the lower surface 304 of the sealing member 300 and the front surface 202 of the semiconductor chip 200, and the first lower redistribution wiring 122 may be formed on the first lower insulating layer 110. The first lower redistribution wiring 122 may be electrically connected to the through vias 350 and the chip pads 210 through first openings formed in the first lower insulating layer 110.

The second lower insulating layer 120 may be formed on the first lower insulating layer 110, and the second lower redistribution wiring 132 may be formed on the first lower insulating layer 120. The second lower redistribution wiring 132 may be electrically connected to the first lower redistribution wiring 122 through second openings formed in the second lower insulating layer 120.

The third lower insulating layer 130 may be formed on the second lower insulating layer 120, and the third lower redistribution wiring 142 may be formed on the second lower insulating layer 120. The third lower redistribution wiring 142 may be electrically connected to the second lower redistribution wiring 132 through third openings formed in the third lower insulating layer 130.

A second connection pad 156 as a lower connection pad may be disposed on the third lower redistribution wiring 142. A solder resist layer 140 serving as the fourth lower insulating layer may be formed on the third lower insulating layer 130 and may expose at least a portion of the second connection pad 156. The solder resist layer 140 may serve as a passivation layer.

The numbers and arrangements of the lower insulating layers and the lower redistribution wirings of the lower redistribution wiring layer are provided as examples, and it will be appreciated that the present disclosure is not limited thereto.

In example embodiments, the lower structure LS may further include a first dielectric layer 310 provided on an upper surface 302 of the sealing member 300. A plurality of first bonding pads 312 may be provided in the first dielectric layer 310 to be connected to end portions of the plurality of through vias 350 respectively.

The substrate structure DS may include a dummy substrate layer 400 having a plurality of through electrodes 450 and a plurality of dummy through electrodes 460 that are formed to penetrate the dummy substrate layer 400. The substrate structure DS may further include a second dielectric layer 410 provided on the first surface 402 of the dummy substrate layer 400. A plurality of second bonding pads 412 may be provided in the second dielectric layer 410 to be connected to end portions of the plurality of through electrodes 450 respectively. No pads may be disposed in contact with a lower surface of the plurality of dummy through electrodes 460.

The first dielectric layer 310 on the upper surface 302 of the sealing member 300 and the second dielectric layer 410 on the first surface 402 of the dummy substrate layer 400 may be bonded to each other. The first dielectric layer 310 on the upper surface 302 of the sealing member 300 and the second dielectric layer 410 on the first surface 402 of the dummy substrate layer 400 may be bonded to each other by hybrid bonding. The first bonding pad 312 of the first dielectric layer 310 and the second bonding pad 412 of the second dielectric layer 410 may be bonded to each other. The first bonding pad 312 of the first dielectric layer 310 and the second bonding pad 412 of the second dielectric layer 410 may be bonded to each other by copper-copper hybrid bonding (Cu—Cu hybrid bonding).

In example embodiments, the upper redistribution wiring layer 500 may be disposed on the second surface 404 of the dummy substrate layer 400 of the substrate structure DS. The upper redistribution wiring layer 500 may include second redistribution wirings 502 electrically connected to the through electrodes 450 respectively. The second redistribution wirings 502 may include upper redistribution wirings stacked in at least two layers on the upper surface 404 of the dummy substrate layer 400. The second redistribution wirings 502 may be provided on the sealing member 300 to serve as backside redistribution wirings. Accordingly, the upper redistribution wiring layer 500 may be a backside redistribution wiring layer (BRDL) of the fan-out package.

In example embodiments, the external connection members 160 may be disposed on the second connection pads 156 on the lower redistribution wiring 142 on the outer surface of the lower redistribution wiring layer 100. For example, the external connection member 160 may include a solder ball. The semiconductor package 13 may be mounted on a module substrate (not illustrated) via the solder balls to form a memory module.

Hereinafter, a method of manufacturing the semiconductor package of FIG. 18 will be described.

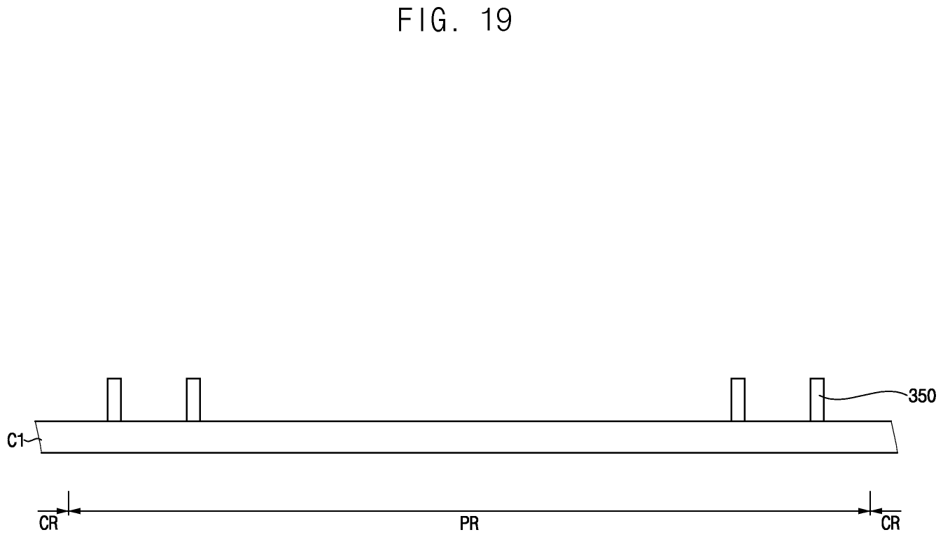

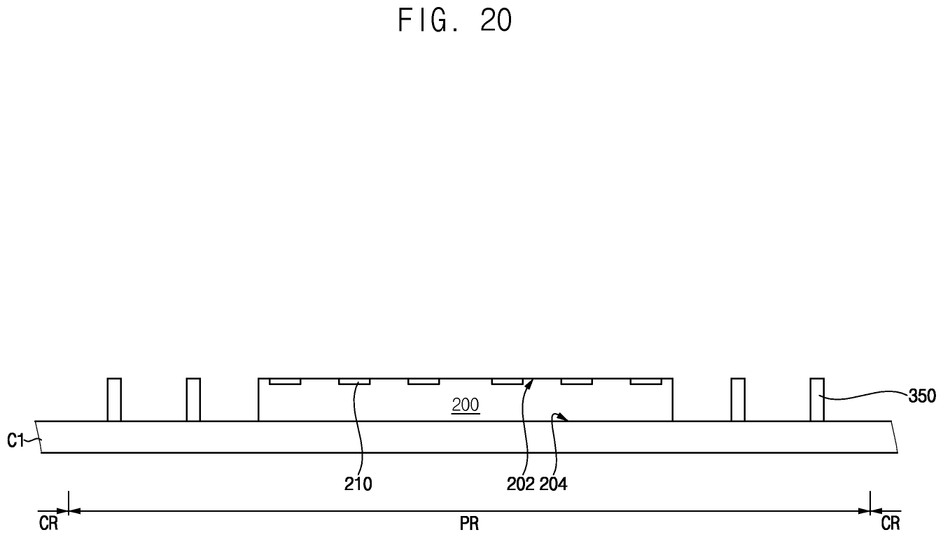

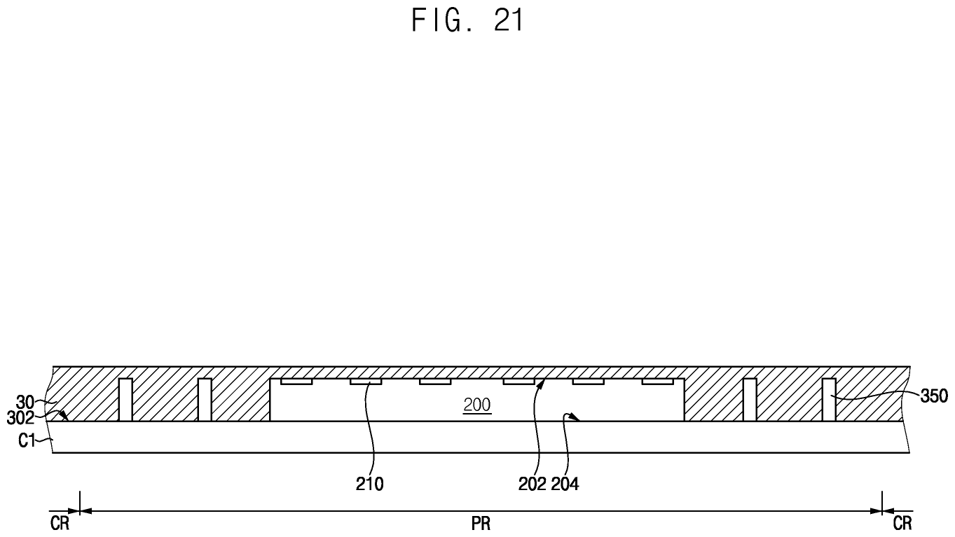

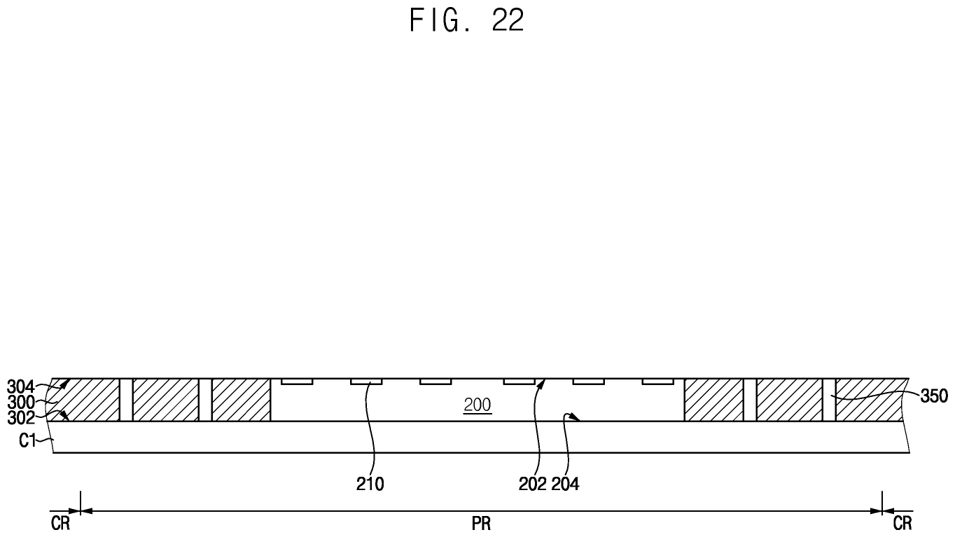

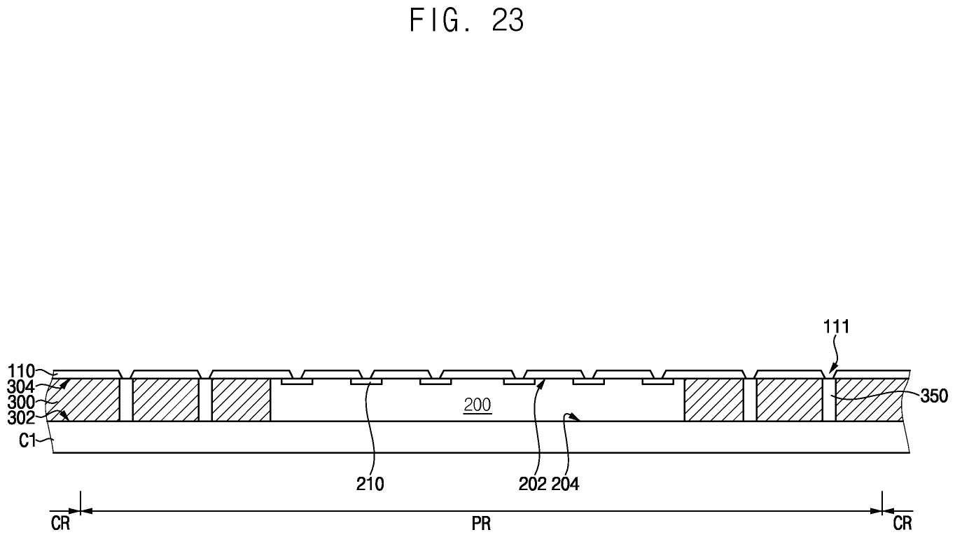

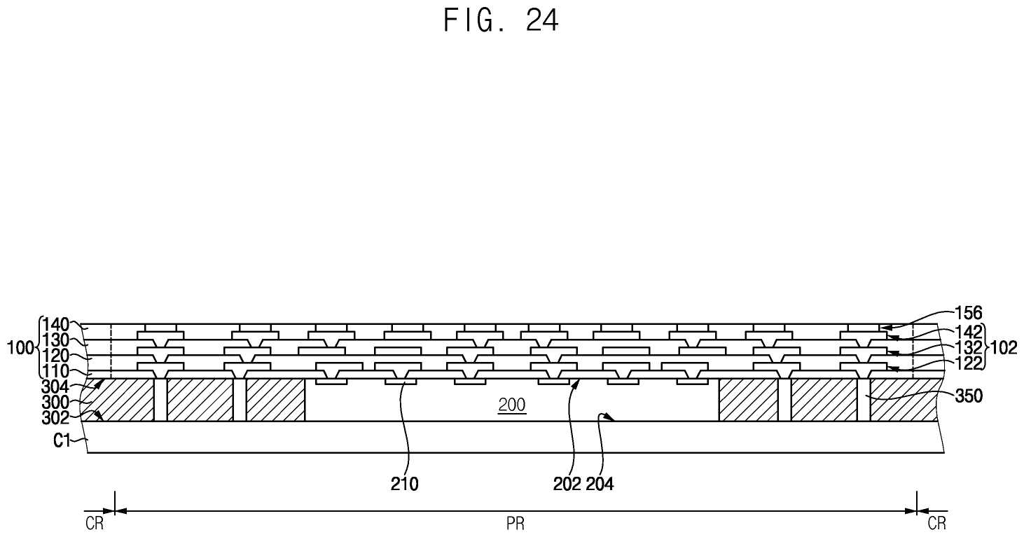

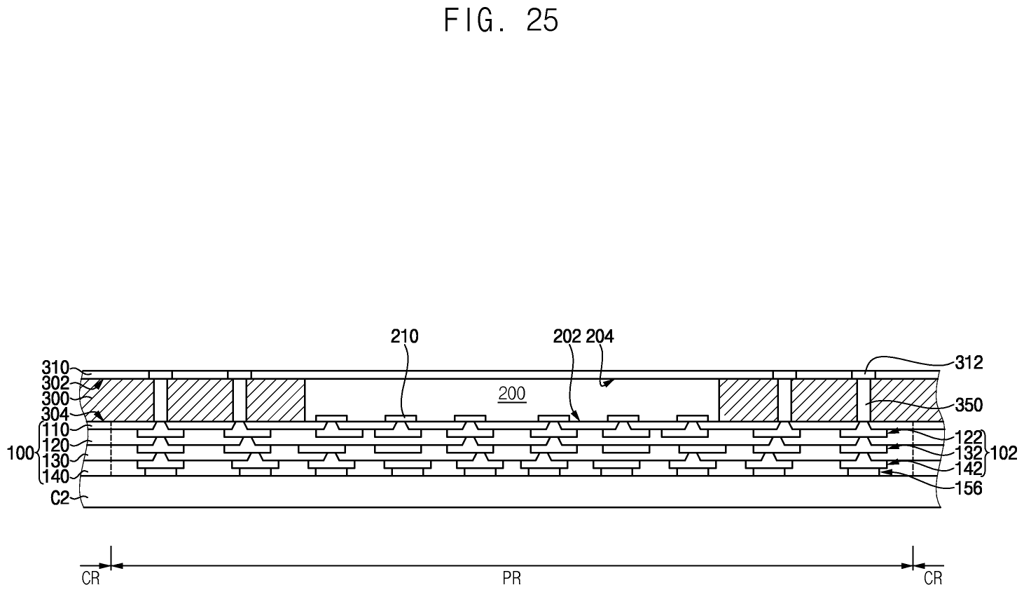

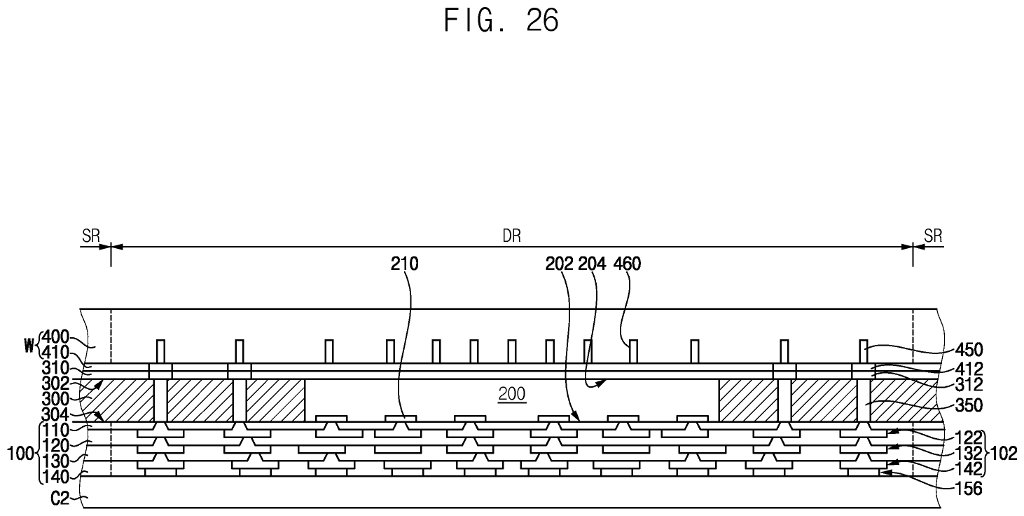

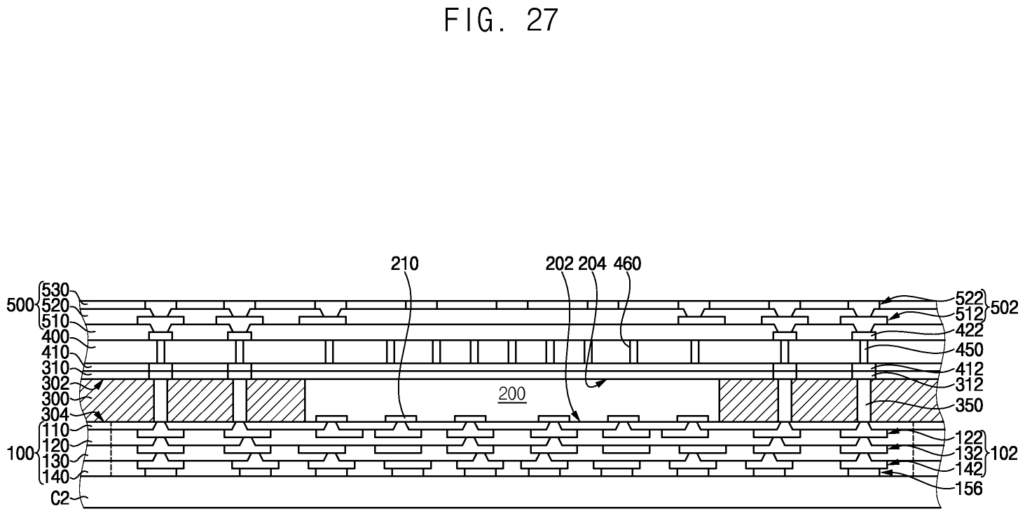

FIGS. 19 to 27 are cross-sectional views illustrating a method of manufacturing a semiconductor package in accordance with example embodiments.

Referring to FIG. 19, a plurality of through vias 350 as conductive structures may be formed on a first carrier substrate C1.

In example embodiments, the first carrier substrate C1 may be used as a base substrate for stacking a plurality of semiconductor chips and forming a sealing member covering them. The first carrier substrate C1 may have a shape corresponding to a wafer on which a semiconductor process may be performed. The first carrier substrate C1 may include a package region PR on which the semiconductor chip may be mounted and a cutting region CA surrounding the package region PR. As described herein, a lower redistribution wiring layer and the sealing member formed on the first carrier substrate C1 may be cut along the cutting region CA that divides the plurality of package regions PR to be individualized.

In particular, a seed layer and a photoresist layer may be formed on the first carrier substrate C1, and an exposure process may be performed on the photoresist layer to form a photoresist pattern having openings that are provided on a fan-out region for forming the plurality of through vias 350.

An electroplating process may be performed to disposed a conductive material in the openings of the photoresist pattern to form the through vias 350. The electroplating process may be performed to fill the openings of the photoresist pattern with a conductive material to form the through vias 350. The photoresist pattern may be removed by a strip process and a portion of the seed layer exposed by the through vias 350 may be removed.

Referring to FIG. 20, at least one semiconductor chip 200 may be disposed on the first carrier substrate C1.

In example embodiments, the semiconductor chip 200 may be disposed in a fan-in region of the first carrier substrate C1. The plurality of through vias 350 may be disposed around the semiconductor chip 200. The plurality of through vias 350 may be disposed surround the semiconductor chip 200 in a plan view. The semiconductor chip 200 may be disposed such that an upper surface 204 (e.g., a backside surface) opposite to a front surface 202, that is, an active surface on which chip pads 210 are formed faces the first carrier substrate C1.

Referring to FIG. 21 and FIG. 22, a sealing material 30 may be formed on the first carrier substrate C1 to cover the semiconductor chip 200 and the plurality of through vias 350, and an upper portion of the sealing material 30 may be removed to form a sealing member 300 that exposes the front surface 202 of the semiconductor chip 200 and upper surfaces of the plurality of through vias 350.

The sealing material 30 may be formed to cover the front surface 202 of the semiconductor chip 200 and the upper surfaces of the plurality of through vias 350. For example, the sealing material 30 may include an epoxy molding compound (EMC).

The upper portion of the sealing material 30 may be removed by a grinding process. As the upper portion of the sealing material 30 may be removed, the chip pads 210 on the front surface 202 of the semiconductor chip 200 and the plurality of through vias 350 may be exposed from a lower surface 304 of the sealing member 300. The sealing member 300 may cover a side surface of the semiconductor chip 200.

Referring to FIG. 23 and FIG. 24, a lower redistribution wiring layer 100 having first redistribution wirings 102 may be formed on the lower surface 304 of the sealing member 300 and the front surface 202 of the semiconductor chip 200.

As illustrated in FIG. 23, processes the same as, or similar to, the processes described with reference to FIG. 4 may be performed to form a first lower insulating layer 110 on the lower surface 304 of the sealing member 300 and the front surface of the semiconductor chip 200, and the first lower insulating layer 110 may be patterned to form first openings 111 that expose the through vias 350 and chip pads 210 respectively.

For example, the first lower insulating layer 110 may include a polymer or a dielectric layer. The first lower insulating layer 110 may include a photosensitive insulating material (PID) or an insulating film such as ABF. The first lower insulating layer may be formed by a spin coating process, a vapor deposition process, etc.

When the first lower insulating layer includes the photosensitive insulating material, the first lower insulating layer may be patterned to form preliminary openings. A curing process of the first lower insulating layer may be performed such that a portion of the first lower insulating layer flows down toward the preliminary opening to form a tapered first opening.

As illustrated in FIG. 24, first lower redistribution wiring 122 may be formed on the first lower insulating layer 110. The first lower redistribution wiring 122 may be electrically connected to the through vias 350 and the chip pads 210 through the first openings of the first lower insulating layer 110.

For example, a seed layer may be formed on portions of the through vias 350 and the chips pads 210 exposed by the first openings, the seed layer may be patterned and an electro plating process may be performed to form the first lower redistribution wiring 122. Accordingly, the first lower redistribution wiring 122 may be electrically connected to the through vias 350 and the chip pads 210 through the first openings of the first lower insulating layer 110.

Similarly, a second lower insulating layer 120 may be formed on the first lower insulating layer 110. The second lower insulating layer 120 may cover the first lower redistribution wiring 122. The second lower insulating layer 120 may be patterned to form second openings that expose at least portions of the first lower redistribution wiring 122. Second lower redistribution wiring 132 may be formed on the second lower insulating layer 120. The second lower redistribution wiring 132 may be electrically connected to the first lower redistribution wiring 122 through the second openings of the second lower insulating layer 120.

A third lower insulating layer 130 may be formed on the second lower insulating layer 120 to cover the second lower redistribution wiring 132 and the third lower insulating layer 130 may be patterned to form third openings that expose at least portions of the second lower redistribution wiring 132. Third lower redistribution wiring 142 may be formed on the third lower insulating layer 130. The third lower redistribution wiring 142 may be electrically connected to the second lower redistribution wiring 132 through the third openings of the third lower insulating layer 130.

Second connection pads 156 may be formed on the third lower redistribution wiring 142. The, a solder resist layer 140 as a fourth lower insulating layer may be formed on the third lower insulating layer 130 to cover the third lower redistribution wiring 142 and expose at least a portion of the second connection pad 156.

Thus, the lower redistribution wiring layer 100 having the first to fourth lower insulating layers 110, 120, 130 and 140 may be formed. The lower redistribution wiring layer 100 may be a front redistribution wiring layer (FRDL) of a fan-out package. The second connection pads 156 may be exposed from an outer surface of the lower redistribution wiring layer 100.

Referring to FIG. 25, processes the same as, or similar to, the processes described with reference to FIG. 9 may be performed to form a first dielectric layer 310 including a plurality of first bonding pads 312 formed therein, on an upper surface 302 of the sealing member 300.

In particular, the first carrier substrate C1 may be removed, the structure of FIG. 24 may be turned over, and the lower redistribution wiring layer 100 may be attached on a second carrier substrate C2. After the first dielectric layer 310 is formed on the upper surface 302 of the sealing member 300, the first dielectric layer 310 may be patterned to form openings that expose end portions of the through vias 350 respectively. The openings of the patterned first dielectric layer 310 may expose upper surfaces of the through vias 350. For example, the first dielectric layer 310 may include silicon oxide, silicon nitride, silicon oxynitride, etc.

After a seed layer is formed on portions of the exposed through vias 350 and in the openings, the seed layer may be patterned, and an electroplating process may be performed to form the first bonding pads 312. Accordingly, the first bonding pads 312 may be electrically connected to the through vias 350 through the openings. An upper surface of the first bonding pad 312 may be located on the same plane as an upper surface of the first dielectric layer 310. For example, a diameter D2 of each of the first bonding pads 312 may be within a range of about 40 μm to 400 μm.

Referring to FIG. 26, processes the same as, or similar to, the processes described with reference to FIG. 10, FIG. 11, and FIG. 12 may be performed to attach a wafer W of FIG. 10 to the sealing member 300 of FIG. 25 (wafer-to-wafer hybrid bonding process).

In example embodiments, the wafer W of FIG. 10 may be bonded to the sealing member 300 on the second carrier substrate C2. The wafer W may be stacked on the sealing member 300 such that a first surface 402 of the dummy substrate layer 400 of the wafer W faces the upper surface 302 of the sealing member 300.

When the sealing member 300 on the second carrier substrate C2 and the dummy substrate layer 400 on the wafer W are bonded to each other by wafer-to-wafer bonding, the first dielectric layer 310 on the upper surface 302 of the sealing member 300 and the second dielectric layer 410 on the first surface 402 of the dummy substrate layer 400 of the wafer W may be hybrid-bonded to each other by a thermal compression process and an annealing process. That is, first dielectric layer on the upper surface 302 of the sealing member 300 may be directly bonded to the second dielectric layer 410 on the first surface 402 of the dummy substrate layer 400 of the wafer W, and the first bonding pad 312 and the second bonding pad 412 may be bonded to each other by copper-copper hybrid bonding (Cu—Cu Hybrid Bonding).

The first dielectric layer 310 and the second dielectric layer 410 may include a dielectric material that contacts each other and provides excellent bonding strength, which may be used as a bonding structure. The first dielectric layer 310 and second dielectric layer 410 may be bonded to each other by a high temperature annealing process while in contact with each other. Here, the bonding structure may have a relatively strong bonding strength by covalent bonding.

Referring to FIG. 27, processes the same as, or similar to, the processes described with reference to FIG. 13 and FIG. 14 may be performed to partially remove a backside surface of the wafer W, that is, the second surface 404 of the dummy substrate layer 400 to expose end portions of the through electrodes 450, and processes the same as, or similar to, the processes described with reference to FIG. 15 may be performed to form an upper redistribution wiring layer 500 having second redistribution wirings 502 on the second surface 404 of the dummy substrate layer 400. The second redistribution wirings 502 as upper redistribution wirings may be electrically connected to the through electrodes 450.

External connection members 160 (see FIG. 18) may be formed on the second connection pad 156 on the outer surface, that is, a lower surface of the lower redistribution wiring layer 100 to be electrically connected to the first redistribution wirings 102 respectively.

A sawing process may be performed to individualize the lower redistribution wiring layer 100, to complete a fan-out wafer level package 13 of FIG. 18 including the sealing member 300, the lower redistribution wiring layer 100 formed on the lower surface 304 of the sealing member 300, the substrate structure DS formed on the upper surface 302 of the sealing member 300, and the upper redistribution wiring layer 500 formed on the substrate structure DS.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a lower redistribution wiring layer having lower redistribution wirings;
at least one semiconductor chip disposed on, and electrically connected to, the lower redistribution wiring layer;
a sealing member disposed on the lower redistribution wiring layer, the sealing member having a plurality of through vias that penetrate the sealing member and are electrically connected to the lower redistribution wirings;
a dummy substrate layer stacked on the sealing member and the at least one semiconductor chip, the dummy substrate layer having a plurality of through electrodes that penetrate the dummy substrate layer and are electrically connected to the plurality of through vias; and
an upper redistribution wiring layer disposed on the dummy substrate layer, the upper redistribution wiring layer having upper redistribution wirings that are electrically connected to the plurality of through electrodes.

2. The semiconductor package of claim 1, further comprising:
a first dielectric layer provided on an upper surface of the sealing member and having a plurality of first bonding pads that are connected to end portions of the plurality of through vias respectively; and
a second dielectric layer forming a lower surface of the dummy substrate layer and having a plurality of second bonding pads that are connected to at least some of the plurality of through electrodes respectively.

3. The semiconductor package of claim 2, wherein the plurality of first bonding pads are in contact with the plurality of second bonding pads respectively, and
the first dielectric layer is in contact with the second dielectric layer.

4. The semiconductor package of claim 2, wherein the first dielectric layer and second dielectric layer include silicon oxide, silicon nitride or silicon oxynitride.

5. The semiconductor package of claim 1, wherein a thickness of the dummy substrate layer is within a range of about 30 μm to 500 μm.

6. The semiconductor package of claim 1, wherein a diameter of each of the plurality of through vias is within a range of about 30 μm to 300 μm, and a diameter of each of the plurality of through electrodes is within a range of about 5 μm to 50 μm.

7. The semiconductor package of claim 1, wherein the dummy substrate layer includes a silicon material.

8. The semiconductor package of claim 1, wherein the plurality of through electrodes comprise a plurality of dummy through electrodes that are provided to penetrate the dummy substrate layer on the at least one semiconductor chip.

9. The semiconductor package of claim 1, wherein the sealing member surrounds the at least one semiconductor chip.

10. The semiconductor package of claim 1, further comprising:
a second package disposed on the upper redistribution wiring layer,
wherein the second package includes a package substrate and at least one second semiconductor chip stacked on the package substrate.

11. A semiconductor package, comprising:
a lower structure including a lower redistribution wiring layer having lower redistribution wirings, at least one semiconductor chip disposed on the lower redistribution wiring layer, and a sealing member disposed on the lower redistribution wiring layer and having a plurality of through vias that penetrate the sealing member and are electrically connected to the lower redistribution wirings;
an upper redistribution wiring layer disposed on the lower structure, the upper redistribution wiring layer having upper redistribution wirings; and
a substrate structure interposed between the lower structure and the upper redistribution wiring layer, the substrate structure including a dummy substrate layer,
wherein a plurality of through electrodes are provided in the dummy substrate layer to penetrate the dummy substrate layer and electrically connect the plurality of through vias and the upper redistribution wirings.

12. The semiconductor package of claim 11,
wherein the lower structure further includes a first dielectric layer provided on an upper surface of the sealing member and having a plurality of first bonding pads that are connected to end portions of the plurality of through vias respectively, and
wherein the substrate structure further includes a second dielectric layer provided on a lower surface of the dummy substrate layer and having a plurality of second bonding pads that are connected to at least some of the plurality of through electrodes respectively.

13. The semiconductor package of claim 12, wherein the plurality of first bonding pads are in contact with the plurality of second bonding pads respectively, and
the first dielectric layer is in contact with the second dielectric layer.

14. The semiconductor package of claim 12, wherein the first dielectric layer and the second dielectric layer include silicon oxide, silicon nitride or silicon oxynitride.

15. The semiconductor package of claim 11, wherein a thickness of the dummy substrate layer is within a range of about 30 μm to 500 μm.

16. The semiconductor package of claim 11, wherein a diameter of each of the plurality of through vias is within a range of about 30 μm to 300 μm, and a diameter of each of the plurality of through electrodes is within a range of about 5 μm to 50 μm.

17. The semiconductor package of claim 11, wherein the dummy substrate layer include a silicon material.

18. The semiconductor package of claim 11, wherein the plurality of through electrodes comprise a plurality of dummy through electrodes that are provided to penetrate the dummy substrate layer on the at least one semiconductor chip.

19. The semiconductor package of claim 11, wherein the sealing member surrounds the at least one semiconductor chip and exposes an upper surface of the at least one semiconductor chip.

20. A semiconductor package, comprising:
a lower redistribution wiring layer having lower redistribution wirings;
at least one semiconductor chip disposed on the lower redistribution wiring layer, the at least one semiconductor chip having chip pads that are electrically connected to the lower redistribution wirings;
a sealing member surrounding the at least one semiconductor chip and disposed on the lower redistribution wiring layer, the sealing member having a plurality of through vias that penetrate the sealing member and are electrically connected to the lower redistribution wirings;
a first dielectric layer provided on an upper surface of the sealing member and having a plurality of first bonding pads that are connected to end portions of the plurality of through vias respectively;
a second dielectric layer bonded to the first dielectric layer and having a plurality of second bonding pads that are in contact with the plurality of first bonding pads respectively;
a dummy substrate layer stacked on the sealing member, the dummy substrate layer having a plurality of through electrodes that penetrate the dummy substrate layer and are electrically connected to the plurality of second bonding pads respectively; and
an upper redistribution wiring layer disposed on the dummy substrate layer, the upper redistribution wiring layer having upper redistribution wirings that are electrically connected to the plurality of through electrodes.
